(19) United States
(12) Patent Application Publication
(10) Pub. No.: US 2024/0203494 A1
(43) Pub. Date: Jun. 20, 2024

(54) SEMICONDUCTOR STORAGE DEVICE AND SEMICONDUCTOR STORAGE DEVICE MANUFACTURING METHOD

(71) Applicant: Kioxia Corporation, Tokyo (JP)

(72) Inventor: Kosei NODA, Yokkaichi Mie (JP)

(73) Assignee: Kioxia Corporation, Tokyo (JP)

(21) Appl. No.: 18/459,103

(22) Filed: Aug. 31, 2023

(30) Foreign Application Priority Data
Dec. 20, 2022 (JP) 2022-203040

(51) Int. Cl. G11C 16/04; H10B 41/10; H10B 41/27; H10B 41/35; H10B 43/10; H10B 43/27; H10B 43/35

(52) U.S. Cl. CPC G11C 16/0483; H10B 41/10; H10B 41/27; H10B 41/35; H10B 43/10; H10B 43/27; H10B 43/35

(57) ABSTRACT

A semiconductor storage device includes a layered body with gate electrode layers and first insulating layers alternately stacked in a first direction; a first columnar body extending in the first direction; and a second columnar body extending in the first direction. The gate electrode layers include a first gate electrode layer and a second gate electrode layer. The second gate layer has a length in a second direction is less than a length of the first gate electrode layer in the second direction. The first columnar body includes a first conductive portion that penetrates the first gate electrode layer in the first direction. The second columnar body includes a second conductive portion that penetrates the second gate electrode layer and the first gate electrode layer in the first direction, and an insulating portion disposed between the first gate electrode layer and the second conductive portion.

### CROSS-REFERENCE TO RELATED APPLICATION(S)

This application is based upon and claims the benefit of priority from Japanese Patent Application No. 2022-203040, filed Dec. 20, 2022, the entire contents of which are incorporated herein by reference.

### FIELD

Embodiments described herein relate generally to a semiconductor storage device and a semiconductor storage device manufacturing method.

### BACKGROUND

A semiconductor storage device may include a multiple of gate electrode layers and a multiple of insulation layers stacked alternately, and a multiple of contacts. The alternately stacked gate electrode layers and insulation layers have a stepped region in which lengths of the multiple of gate electrode layers differ. The multiple of contacts are connected to the multiple of gate electrode layers in the stepped region.

### DESCRIPTION OF THE DRAWINGS

FIG. 1 is a block diagram showing one portion of a configuration of a semiconductor storage device of a first embodiment.

FIG. 2 is a drawing showing an equivalent circuit of one portion of a memory cell array of the first embodiment.

FIG. 3 is a sectional view showing one portion of the memory cell array of the first embodiment.

FIG. 4 is a sectional view along an F4-F4 line of one portion of the memory cell array shown in FIG. 3.

FIG. 5 is a sectional view wherein a region enclosed by an F5 line of the memory cell array shown in FIG. 4 is shown enlarged.

FIG. 6 is a sectional view along an F6-F6 line of the memory cell array shown in FIG. 5.

FIG. 7 is a sectional view showing one portion of the memory cell array of the first embodiment.

FIG. 8 is a sectional view wherein a region enclosed by an F8 line of a stepped region shown in FIG. 3 is shown enlarged.

FIG. 9 is a sectional view showing one portion of the stepped region of the first embodiment.

FIG. 10 is a sectional view along an F10-F10 line of the stepped region shown in FIG. 9.

FIG. 11 is a sectional view along an F11-F11 line of a dummy stepped region shown in FIG. 7.

FIG. 12A is a sectional view illustrating a semiconductor storage device manufacturing method of the first embodiment.

FIG. 12B is a sectional view illustrating a semiconductor storage device manufacturing method of the first embodiment.

FIG. 12C is a sectional view illustrating a semiconductor storage device manufacturing method of the first embodiment.

FIG. 12D is a sectional view illustrating a semiconductor storage device manufacturing method of the first embodiment.

FIG. 12E is a sectional view illustrating a semiconductor storage device manufacturing method of the first embodiment.

FIG. 12F is a sectional view illustrating a semiconductor storage device manufacturing method of the first embodiment.

FIG. 12G is a sectional view illustrating a semiconductor storage device manufacturing method of the first embodiment.

FIG. 12H is a sectional view illustrating a semiconductor storage device manufacturing method of the first embodiment.

FIG. 12I is a sectional view illustrating a semiconductor storage device manufacturing method of the first embodiment.

FIG. 12J is a sectional view illustrating a semiconductor storage device manufacturing method of the first embodiment.

FIG. 12K is a sectional view illustrating a semiconductor storage device manufacturing method of the first embodiment.

FIG. 12L is a sectional view illustrating a semiconductor storage device manufacturing method of the first embodiment.

FIG. 13 is a sectional view showing one portion of a semiconductor storage device of a first modification of the first embodiment.

FIG. 14 is a sectional view showing one portion of a semiconductor storage device of a second modification of the first embodiment.

FIG. 15A is a sectional view illustrating a semiconductor storage device manufacturing method of the second modification.

FIG. 15B is a sectional view illustrating a semiconductor storage device manufacturing method of the second modification.

FIG. 15C is a sectional view illustrating a semiconductor storage device manufacturing method of the second modification.

FIG. 15D is a sectional view illustrating a semiconductor storage device manufacturing method of the second modification.

FIG. 15E is a sectional view illustrating a semiconductor storage device manufacturing method of the second modification.

FIG. 15F is a sectional view illustrating a semiconductor storage device manufacturing method of the second modification.

FIG. 16 is a sectional view showing one portion of a semiconductor storage device of a second embodiment.

FIG. 17A is a sectional view illustrating a semiconductor storage device manufacturing method of the second embodiment.

FIG. 17B is a sectional view illustrating a semiconductor storage device manufacturing method of the second embodiment.

FIG. 17C is a sectional view illustrating a semiconductor storage device manufacturing method of the second embodiment.

FIG. 17D is a sectional view illustrating a semiconductor storage device manufacturing method of the second embodiment.

FIG. 17E is a sectional view illustrating a semiconductor storage device manufacturing method of the second embodiment.

FIG. 17F is a sectional view illustrating a semiconductor storage device manufacturing method of the second embodiment.

FIG. 17G is a sectional view illustrating a semiconductor storage device manufacturing method of the second embodiment.

FIG. 17H is a sectional view illustrating a semiconductor storage device manufacturing method of the second embodiment.

FIG. 18 is a sectional view showing one portion of a semiconductor storage device of a third embodiment.

FIG. 19 is a sectional view showing one portion of a semiconductor storage device of a fourth embodiment.

### DETAILED DESCRIPTION

Embodiments provide an improvement in reliability of a semiconductor storage device.

In general, according to one embodiment, a semiconductor storage device includes a layered body including a plurality of gate electrode layers and a plurality of first insulating layers alternately stacked on top of one another in a first direction; a first columnar body extending in the first direction; and a second columnar body extending in the first direction. The gate electrode layers include a first gate electrode layer, and a second gate electrode layer that is disposed on a first side in the first direction with respect to the first gate electrode layer, and the second gate layer has a length in a second direction that intersects the first direction that is less than a length of the first gate electrode layer in the second direction. The first columnar body includes a first conductive portion that penetrates the first gate electrode layer in the first direction and is electrically connected to the first gate electrode layer. The second columnar body includes a second conductive portion that penetrates the second gate electrode layer and the first gate electrode layer in the first direction and is electrically connected to the second gate electrode layer, and an insulating portion disposed between the first gate electrode layer and the second conductive portion. The first gate electrode layer includes a barrier metal film. At least one end portion in the second direction of the barrier metal film is positioned between at least one portion of the first conductive portion and the second conductive portion with regard to the second direction, and extends in a third direction that intersects the first direction and the second direction.

Hereafter, a semiconductor storage device and a semiconductor storage device manufacturing method of an embodiment will be described, with reference to the drawings. In the following description, identical reference signs will be allotted to configurations having identical or similar functions. Further, there is a case wherein a redundant description of the configurations is omitted. With regard to reference signs having a numeral or a letter as a suffix for purposes of differentiation in the following description, there is a case wherein the numeral or letter suffix is omitted when the reference signs need not be differentiated from each other.

In the present application, terminology is defined as follows. “Parallel”, “perpendicular”, and “the same” may include cases of being “approximately parallel”, “approximately perpendicular”, and “approximately the same” respectively. “Connection”, not being limited to a mechanical connection, may include an electrical connection. That is, “connection”, not being limited to a case wherein a multiple of elements are directly connected, may include a case wherein a multiple of elements are connected via another element interposed therebetween. “Coincide”, not being limited to a case wherein a multiple of elements are in contact, may include a case wherein a multiple of elements coincide across another element interposed therebetween. “Layer” and “film” are items of terminology used separately for the sake of convenience in order to differentiate between constituent elements, and substantially mean the same thing. Because of this, “layer” and “film” may be interchanged in the following description.

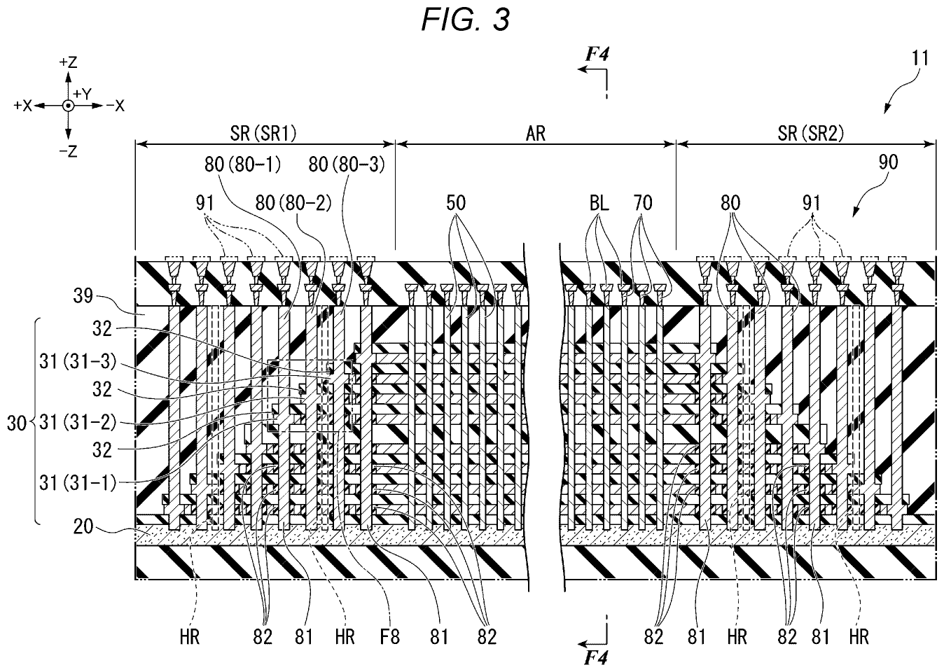

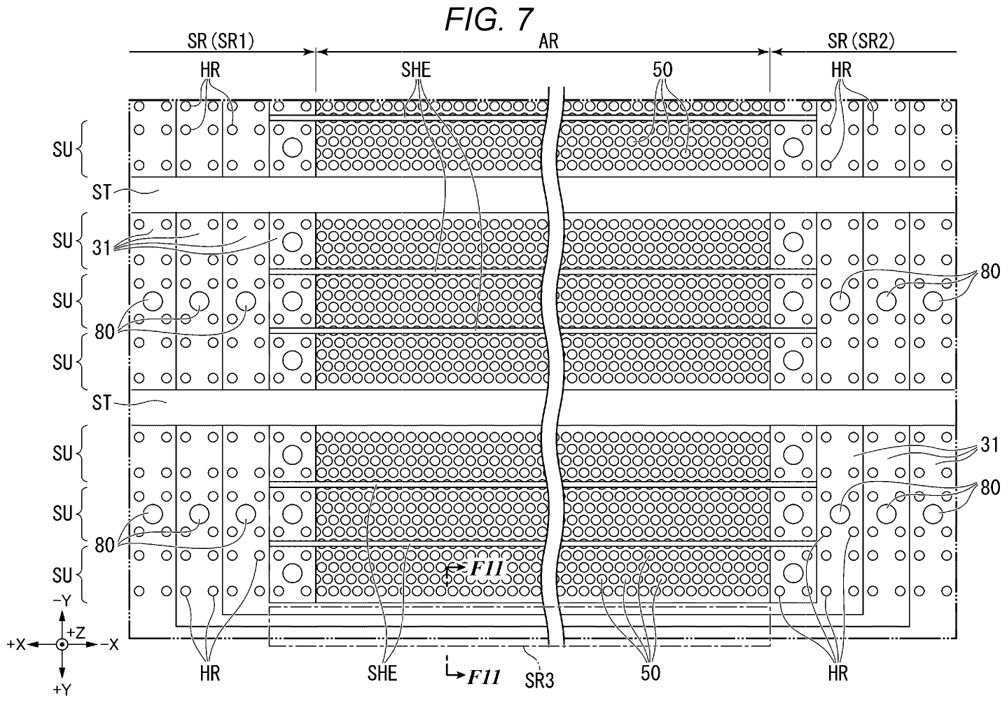

A +X direction, a −X direction, a +Y direction, a −Y direction, a +Z direction, and a −Z direction are defined as follows. The +X direction is a direction in which a word line WL to be described hereafter extends, and is a direction from a second stepped region SR2, to be described hereafter, toward a first stepped region SR1 (refer to FIG. 3). The −X direction is a direction opposite to the +X direction. When not differentiating between the two, the +X direction and the −X direction are called simply an X direction. The +Y direction is a direction that intersects (for example, is perpendicular to) the X direction, and is a direction from one dividing portion ST, to be described hereafter, toward another dividing portion ST (refer to FIG. 7). The −Y direction is a direction opposite to the +Y direction. When not differentiating between the two, the +Y direction and the −Y direction are called simply a Y direction. The +Z direction is a direction that intersects (for example, is perpendicular to) the X direction and the Y direction. The +Z direction is a direction from a layered body 30, to be described hereafter, toward a bit line BL (refer to FIG. 3). The −Z direction is a direction opposite to the +Z direction. When not differentiating between the two, the +Z direction and the −Z direction are called simply a Z direction.

In the following description, there is a case wherein a +Z direction side is called “top” and a −Z direction side is called “bottom”. Also, in the following description, there is a case wherein a position in a Z direction is called “height”. These expressions are for the sake of convenience, and do not regulate a direction of a force of gravity. The Z direction is one example of the “first direction”. The +Z direction side is one example of the “first side in the first direction”. The X direction is one example of the “second direction”. The Y direction is one example of the “third direction”. In the drawings to be described hereafter, there is a case wherein a depiction of a configuration unrelated to the description is omitted. In the drawings to be described hereafter, there is a case wherein the number of one portion of configurations (for example, conductive layers) is schematic.

### First Embodiment

### 1. Semiconductor Storage Device Configuration

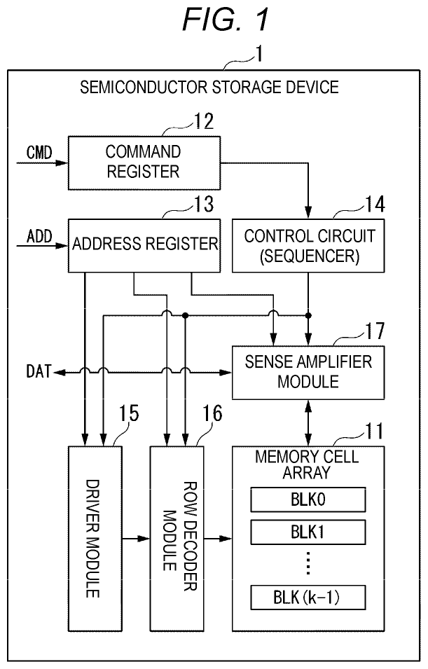

FIG. 1 is a block diagram showing one portion of a configuration of a semiconductor storage device 1. The semiconductor storage device 1, being, for example, a non-volatile semiconductor storage device, is a NAND flash memory. The semiconductor storage device 1 can be connected to, for example, an external host device, and is used as a storage space of the host device. The semiconductor storage device 1 includes, for example, a memory cell array 11, a command register 12, an address register 13, a control circuit (sequencer) 14, a driver module 15, a row decoder module 16, and a sense amplifier module 17.

The memory cell array 11 includes a multiple of blocks BLK0 to BLK (k−1) (k is an integer greater than 1). There is a case wherein the blocks BLK are a multiple of memory cell transistors. The blocks BLK are used as data erasure units. A multiple of bit lines and a multiple of word lines are provided in the memory cell array 11. Each memory cell transistor is correlated to one bit line and one word line.

The command register 12 holds a command CMD received from the host device by the semiconductor storage device 1. The address register 13 holds address information ADD received from the host device by the semiconductor storage device 1. The address information ADD is used in a selection of the block BLK, a word line, and a bit line. The control circuit 14 controls various kinds of operation of the semiconductor storage device 1. For example, the control circuit 14 executes a data write operation, a read operation, an erasure operation, or the like based on the command CMD stored in the command register 12.

The driver module 15 includes a voltage generating circuit, and generates voltage used in various kinds of operation of the semiconductor storage device 1. The row decoder module 16 transfers voltage applied to a signal line corresponding to a selected word line to the selected word line. The sense amplifier module 17 applies a desired voltage to each bit line during a write operation. The sense amplifier module 17, based on the voltage of each bit line, determines a data value stored in each memory cell transistor during a read operation, reads a result of the determination, and transfers the result as data DAT to the host device.

### 2. Memory Cell Array Electrical Configuration

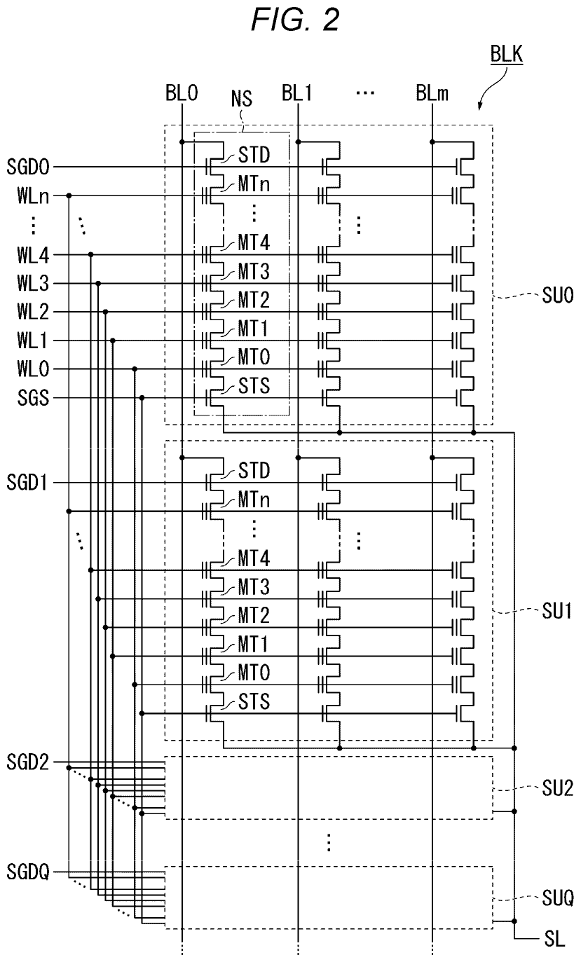

FIG. 2 is a drawing showing an equivalent circuit of one portion of the memory cell array 11. FIG. 2 shows one block BLK in the memory cell array 11. The block BLK includes a multiple of string units SU0 to SUQ (Q is an integer of 1 or greater).

Each string unit SU includes a multiple of NAND strings NS correlated one each to bit lines BL0 to BLm (m is an integer of 1 or greater). Each NAND string NS includes, for example, a multiple of memory cell transistors MT0 to MTn (n is an integer of 1 or greater), one or more drain side select transistors STD, and one or more source side select transistors STS.

The memory cell transistors MT0 to MTn are connected in series in each NAND string NS. Each memory cell transistor MT includes a control gate and a charge storage portion. The control gate of the memory cell transistor MT is connected to one of the word lines WL0 to WLn. Each memory cell transistor MT is such that a charge is accumulated in the charge storage portion in accordance with a voltage applied to the control gate via the word line WL, and the memory cell transistor MT holds a data value in a non-volatile manner.

A drain of the drain side select transistor STD is connected to the bit line BL corresponding to the relevant NAND string NS. A source of the drain side select transistor STD is connected to one end of the serially-connected memory cell transistors MT0 to MTn. A control gate of the drain side select transistor STD is connected to one of drain side select gate lines SGD0 to SDGQ. The drain side select transistor STD is electrically connected to the row decoder module 16 via the drain side select gate line SGD. When a predetermined voltage is applied to the corresponding drain side select gate line SGD, the drain side select transistor STD connects the NAND string NS and the bit line BL.

A drain of the source side select transistor STS is connected to the other end of the serially-connected memory cell transistors MT0 to MTn. A source of the source side select transistor STS is connected to a source line SL. A control gate of the source side select transistor STS is connected to a source side select gate line SGS. When a predetermined voltage is applied to the source side select gate line SGS, the source side select transistor STS connects the NAND string NS and the source line SL.

In the same block BLK, the control gates of the memory cell transistors MT0 to MTn are connected to the corresponding word lines WL0 to WLn. In the same string unit SU, the control gates of the drain side select transistors STD are connected to the corresponding drain side select gate lines SGD0 to SGDQ. The control gates of the source side select transistors STS are connected to the source side select gate line SGS. In the memory cell array 11, the bit line BL is shared by NAND strings NS to which the same column address is allotted in the multiple of string units SU.

### 3. Memory Cell Array Physical Configuration

Next, a physical configuration of the memory cell array 11 will be described.

FIG. 3 is a sectional view showing one portion of the memory cell array 11. The memory cell array 11 has, for example, a lower structure 20, a layered body 30, an insulating portion 39, a multiple of memory pillars 50, a multiple of memory pillar contacts 70, a multiple of conductive layer contacts 80, an upper wiring portion 90, a supporting body HR, a multiple of dividing portions ST (refer to FIG. 7), and a multiple of upper dividing portions SHE (refer to FIG. 7).

### 3.1 Lower Structure

Firstly, the lower structure 20 will be described.

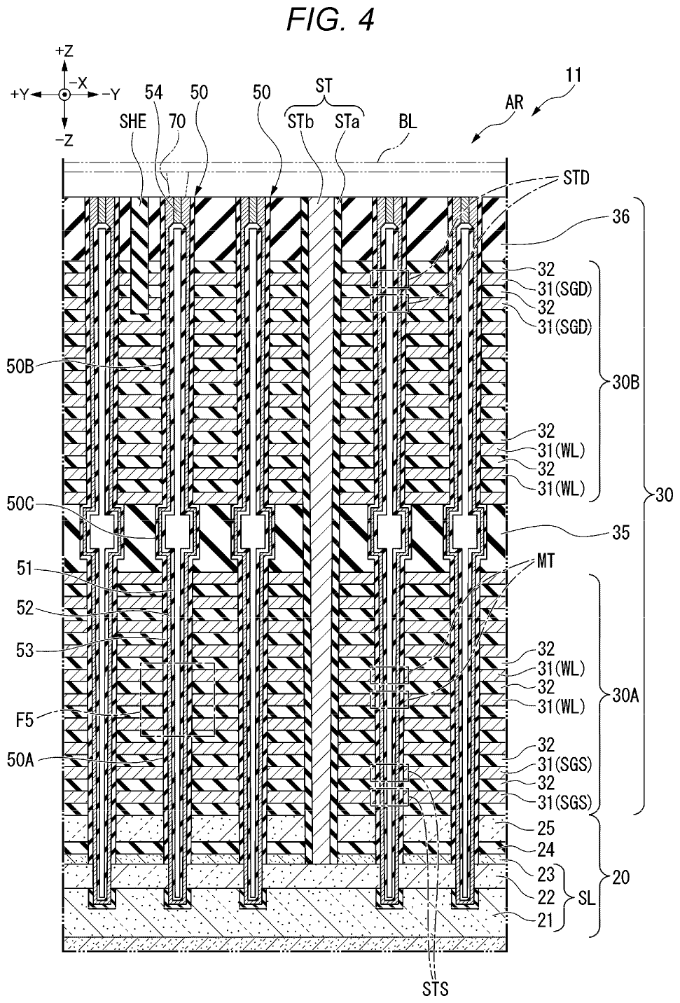

FIG. 4 is a sectional view along an F4-F4 line of one portion of the memory cell array 11 shown in FIG. 3. The lower structure 20 includes, for example, a first semiconductor layer 21, a second semiconductor layer 22, a third semiconductor layer 23, an insulating layer 24, and a fourth semiconductor layer 25.

The first semiconductor layer 21 is a layer formed of a semiconductor material such as polysilicon. The first semiconductor layer 21 includes an impurity, and has conductivity. The first semiconductor layer 21 follows the X direction and the Y direction.

The second semiconductor layer 22 is provided on the first semiconductor layer 21. The second semiconductor layer 22 is a layer formed of a semiconductor material such as polysilicon. The second semiconductor layer 22 includes an impurity, and has conductivity. The second semiconductor layer 22 follows the X direction and the Y direction.

The third semiconductor layer 23 is provided on the second semiconductor layer 22. The third semiconductor layer 23 is a layer formed of a semiconductor material such as polysilicon. The third semiconductor layer 23 includes an impurity, and has conductivity. The third semiconductor layer 23 follows the X direction and the Y direction. A thickness of the third semiconductor layer 23 is, for example, less than a thickness of the first semiconductor layer 21 and a thickness of the second semiconductor layer 22. In the present embodiment, the source line SL is formed of the first semiconductor layer 21, the second semiconductor layer 22, and the third semiconductor layer 23.

The insulating layer 24 is provided on the third semiconductor layer 23. The insulating layer 24 is a layer formed of an insulating material such as silicon oxide. The insulating layer 24 follows the X direction and the Y direction.

The fourth semiconductor layer 25 is provided on the insulating layer 24. The fourth semiconductor layer 25 is a layer that functions as a stopper layer when a groove for providing the dividing portion ST, to be described hereafter, is formed in the layered body 30. The fourth semiconductor layer 25 is formed of a semiconductor material such as polysilicon. A stopper layer formed of an insulating material may be provided instead of the fourth semiconductor layer 25.

### 3. 2 Layered Body

Next, the layered body 30 will be described. The layered body 30 includes a first layered body 30A, a second layered body 30B, an intermediate insulating layer 35, and an upper insulating layer 36.

### 3. 2. 1 First Layered Body

The first layered body 30A is provided on the lower structure 20. The first layered body 30A includes a multiple of conductive layers 31 and a multiple of insulating layers 32. One each of the multiple of conductive layers 31 and the multiple of insulating layers 32 are stacked alternately in the Z direction. In the present application, “a conductive layer and an insulating layer are stacked” may include a case wherein another layer (for example, one portion of a block insulating film 63) is provided between the conductive layer 31 and the insulating layer 32, as will be described hereafter.

The conductive layer 31 is a layer following the X direction and the Y direction. The conductive layer 31 is formed of a conductive material (for example, a metal material) such as tungsten or molybdenum. The conductive layer 31 is one example of a “gate electrode layer”.

The insulating layer 32 is an interlayer insulating film that is provided between two conductive layers 31 neighboring in the Z direction, and insulates the two conductive layers 31. The insulating layer 32 is a layer that follows the X direction and the Y direction. The insulating layer 32 is formed of an insulating material such as silicon oxide. The insulating layer 32 is one example of a “first insulating layer”.

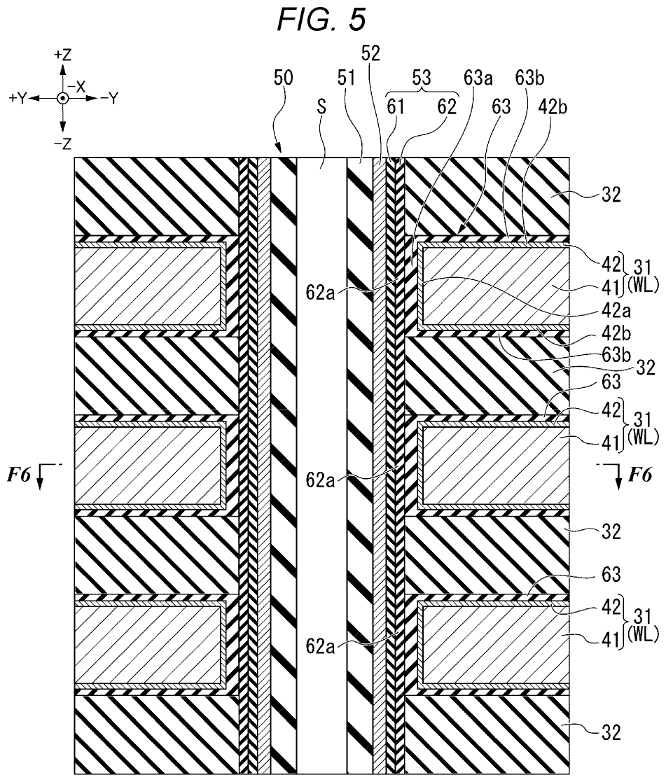

FIG. 5 is a sectional view wherein a region enclosed by an F5 line of the memory cell array 11 shown in FIG. 4 is shown enlarged. In the present embodiment, each conductive layer 31 includes a conductive layer main body 41 and a barrier metal film 42.

### Conductive Layer Main Body

The conductive layer main body 41 forms a greater portion of the conductive layer 31. The conductive layer main body 41 is of a plate form that follows the X direction and the Y direction. The conductive layer main body 41 is formed of a conductive material (for example, a metal material) such as tungsten or molybdenum.

### Barrier Metal Film

The barrier metal film 42 is a layer that restricts a spreading of the material of the conductive layer main body 41 (for example, a spreading to the memory pillar 50, to be described hereafter). The barrier metal film 42 is formed of, for example, titanium nitride or a layered structure film of titanium nitride and titanium. The barrier metal film 42, not being limited to the aforementioned examples, may be formed of another material that can be expected to restrict a spreading of the material of the conductive layer main body 41.

In the present embodiment, the barrier metal film 42 has, for example, a first portion 42a and a second portion 42b. The first portion 42a is disposed between the conductive layer main body 41 and the memory pillar 50. The first portion 42a is formed in a ring form that encloses the memory pillar 50, and extends in the Z direction. The second portion 42b is disposed both between the conductive layer main body 41 and the insulating layer 32 positioned on an upper side of the relevant conductive layer main body 41 and between the conductive layer main body 41 and the insulating layer 32 positioned on a lower side of the relevant conductive layer main body 41. The second portion 42b extends in the X direction and the Y direction along a boundary between the conductive layer main body 41 and the insulating layer 32. In the present embodiment, the second portion 42b is disposed both between the conductive layer main body 41 and a second portion 63b of the block insulating film 63, to be described hereafter, positioned on the upper side of the relevant conductive layer main body 41 and between the conductive layer main body 41 and the second portion 63b of the block insulating film 63 positioned on the lower side of the relevant conductive layer main body 41.

### 3. 2. 2 Second Layered Body

Returning to FIG. 4, a remaining configuration of the layered body 30 will be described.

The second layered body 30B is disposed above the first layered body 30A. In the same way as the first layered body 30A, the second layered body 30B includes a multiple of conductive layers 31 and a multiple of insulating layers 32. One each of the multiple of conductive layers 31 and the multiple of insulating layers 32 are stacked alternately in the Z direction. Details of the conductive layer 31 and the insulating layer 32 of the second layered body 30B are the same as the details described in relation to the conductive layer 31 and the insulating layer 32 of the first layered body 30A.

### 3. 2. 3 Intermediate Insulating Layer

The intermediate insulating layer 35 is disposed between the first layered body 30A and the second layered body 3B in the Z direction. A thickness in the Z direction of the intermediate insulating layer 35 is greater than a thickness in the Z direction of the insulating layer 32. The intermediate insulating layer 35 is a layer in which a connecting portion 50C of the memory pillar 50, to be described hereafter, is provided. The intermediate insulating layer 35 extends in the X direction and the Y direction. The intermediate insulating layer 35 is formed of an insulating material such as silicon oxide.

### 3. 2. 4 Upper Insulating Layer

The upper insulating layer 36 is provided above the second layered body 30B. The upper insulating layer 36 is formed of, for example, silicon oxide. The upper insulating layer 36 extends in the X direction and the Y direction.

### 3. 2. 5 Layered Body Electrical Configuration

Next, an electrical configuration of the layered body 30 will be described.

Of the multiple of conductive layers 30, one or more (for example, a multiple) of the conductive layers 31 separated farthest from the lower structure 20 functions as the drain side select gate line SGD. The drain side select gate line SGD is provided commonly with respect to the multiple of memory pillars 50 aligned in the X direction or the Y direction. A portion in which the drain side select gate line SGD and a channel layer 52 (to be described hereafter) of each memory pillar 50 intersect functions as the drain side select transistor STD.

Of the multiple of conductive layers 31, one or more (for example, a multiple) of the conductive layers 31 separated nearest to the lower structure 20 functions as the source side select gate line SGS. The source side select gate line SGS is provided commonly with respect to the multiple of memory pillars 50 aligned in the X direction or the Y direction. A portion in which the source side select gate line SGS and the channel layer 52 of each memory pillar 50 intersect functions as the source side select transistor STS.

Of the multiple of conductive layers 31, the remainder of the conductive layers 31 sandwiched by the conductive layers 31 functioning as the drain side select gate line SGD or the source side select gate line SGS function as the word line WL. The word line WL is provided commonly with respect to the multiple of memory pillars 50 aligned in the X direction and the Y direction. In the present embodiment, a portion in which the word line WL and the channel layer 52 of each memory pillar 50 intersect functions as the memory cell transistor MT. The memory cell transistor MT will be described in detail hereafter.

### 3. 2. 6 Array Region and Stepped Region

Returning to FIG. 3, some regions included in the layered body 30 will be described. The layered body 30 has, for example, an array region AR, the first stepped region SR1, and the second stepped region SR2.

The array region AR is a region in which the multiple of memory pillars 50, to be described hereafter, are provided, and which can store data. The array region AR is disposed between the first stepped region SR1 and the second stepped region SR2 in the X direction.

The first stepped region SR1 is disposed on the +X direction side of the array region AR. The first stepped region SR1 is a region wherein lengths in the X direction of the multiple of conductive layers 31 differ. In the first stepped region SR1, the multiple of conductive layers 31 are such that the length in the X direction (for example, the length in the +X direction) is greater the farther downward the conductive layer 31 is positioned. Also, in the first stepped region SR1, the multiple of insulating layers 32 are such that the length in the X direction (for example, the length in the +X direction) is greater the farther downward the insulating layer 32 is positioned.

The second stepped region SR2 is disposed on the −X direction side of the array region AR. In the same way as the first stepped region SR1, the second stepped region SR2 is a region wherein the lengths in the X direction of the multiple of conductive layers 31 differ. In the second stepped region SR2, the multiple of conductive layers 31 are such that the length in the X direction (for example, the length in the −X direction) is greater the farther downward the conductive layer 31 is positioned. Also, in the second stepped region SR2, the multiple of insulating layers 32 are such that the length in the X direction (for example, the length in the −X direction) is greater the farther downward the insulating layer 32 is positioned.

A configuration of the second stepped region SR2 is the same as a configuration of the first stepped region SR1. Because of this, it is sufficient with regard to a description relating to the second stepped region SR2 that “+X direction” is replaced with “−X direction” in a description of the first stepped region SR1 given below. Hereafter, the first stepped region SR1 and the second stepped region SR2 will be called simply the “stepped region SR” when not differentiating between the two.

### 3. 3 Insulating Portion

Next, the insulating portion 39 will be described.

The insulating portion 39 is a portion for embedding the stepped region SR. The insulating portion 39 is, for example, provided across the array region AR, the first stepped region SR1, and the second stepped region SR2. The insulating portion 39 is formed of an insulating material such as silicon oxide. The insulating portion 39 is formed using, for example, TEOS (tetraethyl orthosilicate (Si(OC₂H₅)₄).

### 3. 4 Memory Pillar

Next, the memory pillar 50 will be described.

As shown in FIG. 3, the multiple of memory pillars 50 are provided in the array region AR. The multiple of memory pillars 50 are disposed aligned in the X direction and the Y direction.

As shown in FIG. 4, each memory pillar 50 extends in the Z direction, and penetrates the layered body 30, the fourth semiconductor layer 25, the insulating layer 24, the third semiconductor layer 23, and the second semiconductor layer 22. A lower end portion of each memory pillar 50 is embedded in the first semiconductor layer 21.

In the present embodiment, each memory pillar 50 is, for example, a pillar of a two-stepped configuration, and includes a lower pillar 50A, an upper pillar 50B, and the connecting portion 50C. The lower pillar 50A extends in the Z direction in the first layered body 30A. The upper pillar 50B extends in the Z direction in the second layered body 30B. The connecting portion 50C is disposed in the intermediate insulating layer 35. The connecting portion 50C is provided between the lower pillar 50A and the upper pillar 50B in the Z direction, and connects the lower pillar 50A and the upper pillar 50B.

Next, an internal configuration of the memory pillar 50 will be described.

As shown in FIG. 5, the memory pillar 50 has, for example, an insulating core 51, a channel layer 52, a memory film 53, and a cap portion 54 (refer to FIG. 4).

### Insulating Core

The insulating core 51 is provided on an inner peripheral side of the channel layer 52. The insulating core 51 fills one portion of an interior of the channel layer 52. The insulating core 51 is formed of an insulating material such as silicon oxide. The insulating core 51 extends in the Z direction in such a way as to extend over a greater portion of the memory pillar 50, excepting an upper end portion of the memory pillar 50. One portion of the insulating core 51 is formed in a ring form that follows an inner peripheral face of the channel layer 52, and may have a space portion (an air gap) S in an interior.

### Channel Layer

The channel layer 52 is provided between the insulating core 51 and the memory film 53. The channel layer 52 is formed in a ring form, and extends in the Z direction in such a way as to extend over a whole length (whole height) of the memory pillar 50. In the present embodiment, a portion of the memory film 53 positioned at the same height as the source line SL is omitted (refer to FIG. 4). Because of this, a lower end portion of the channel layer 52 is connected to the source line SL by coming into contact with the source line SL. The channel layer 52 is formed of a semiconductor material such as polysilicon. The channel layer 52 may be doped with an impurity. When a voltage is applied to the word line WL, the channel layer 52 forms a channel, thereby electrically connecting the bit line BL and the source line SL.

### Memory Film

The memory film 53 is provided on an outer peripheral side of the channel layer 52. The memory film 53 is disposed between the multiple of conductive layers 31 and the channel layer 52. The memory film 53 is formed in a ring form, and extends in the Z direction in such a way as to extend over the whole length (whole height) of the memory pillar 50. The memory film 53 includes, for example, a tunnel insulating film 61 and a charge trapping film 62.

The tunnel insulating film 61 is positioned between the channel layer 52 and the charge trapping film 62. The tunnel insulating film 61 is, for example, formed in a ring form that follows an outer peripheral face of the channel layer 52, and extends in the Z direction along the channel layer 52. The tunnel insulating film 61 is a potential barrier between the channel layer 52 and the charge trapping film 62. The tunnel insulating film 61 includes silicon oxide, or silicon oxide and silicon nitride.

The charge trapping film 62 is provided on an outer peripheral side of the tunnel insulating film 61. The charge trapping film 62 is disposed between the tunnel insulating film 61 and the block insulating film 63, to be described hereafter. The charge trapping film 62 is, for example, formed in a ring form that follows an outer peripheral face of the tunnel insulating film 61, and extends in the Z direction along the tunnel insulating film 61. The charge trapping film 62 is a functional film that has a large number of crystal defects (trap levels), and can trap a charge in the crystal defects. The charge trapping film 62 is formed of, for example, silicon nitride. A portion 62a of the charge trapping film 62 aligned with each word line WL is one example of a “charge storage portion” that can store information by accumulating a charge.

### Block Insulating Film

Herein, the block insulating film 63 will be described as a configuration relating to the memory pillar 50. The block insulating film 63 is provided on an outer peripheral side of the charge trapping film 62. One portion of the block insulating film 63 is disposed between the conductive layer 31 and the charge trapping film 62. One portion of the block insulating film 63 is, for example, formed in a ring form that follows an outer peripheral face of the charge trapping film 62, and extends in the Z direction along the charge trapping film 62. The block insulating film 63 is an insulating film that restricts back tunneling. Back tunneling is a phenomenon wherein a charge is injected from the word line WL to the charge trapping film 62. The block insulating film 63 is, for example, a film of a layered structure wherein a multiple of insulating films such as silicon oxide films or metal oxide films are stacked. One example of a metal oxide is aluminum oxide. The block insulating film 63 may include a high dielectric constant material (high-k material) such as silicon nitride or hafnium oxide.

In the present embodiment, one portion of the block insulating film 63 is provided between the conductive layer 31 and the insulating layer 32. That is, the block insulating film 63 has a first portion 63a and a second portion 63b. The first portion 63a is disposed between the charge trapping film 62 and the conductive layer 31. The first portion 63a is, for example, formed in a ring form that follows the outer peripheral face of the charge trapping film 62, and extends in the Z direction along the charge trapping film 62. The second portion 61b is provided both between the conductive layer 31 and the insulating layer 32 positioned on an upper side of the relevant conductive layer 31, and between the conductive layer 31 and the insulating layer 32 positioned on a lower side of the relevant conductive layer 31. The second portion 61b extends in the X direction and the Y direction along a boundary between the conductive layer 31 and the insulating layer 32.

A form of the block insulating film 63 is not limited to the aforementioned example. For example, a whole of the block insulating film 63 may be formed in a ring form that follows the outer peripheral face of the charge trapping film 62, and extend in the Z direction along the charge trapping film 62.

### Memory Cell Transistor

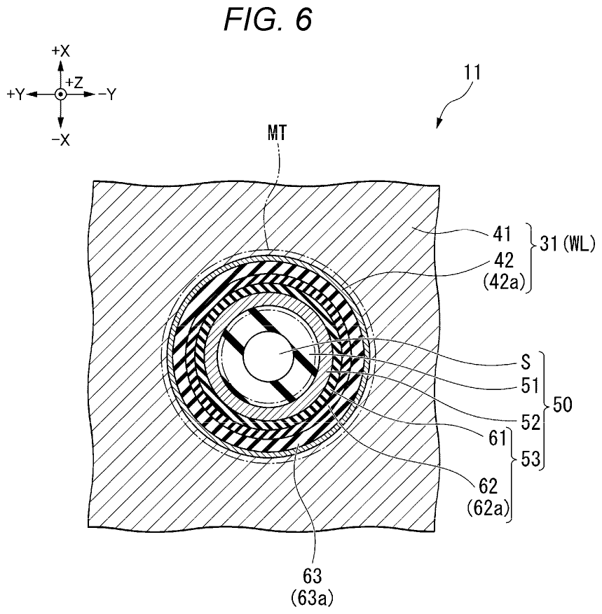

FIG. 6 is a sectional view along an F6-F6 line of the memory cell array 11 shown in FIG. 5. According to the heretofore described configuration, the MANOS (metal-aluminum-nitride-oxide-silicon) type memory cell transistor MT is formed of an end portion of the word line WL neighboring the memory pillar 50, the block insulating film 63, the charge trapping film 62, the tunnel insulating film 61, and the channel layer 52 at the same height as each word line WL. The memory film 53 may have a floating gate type charge storage portion (floating gate electrode) as a charge storage portion instead of the charge trapping film 62. The floating gate electrode is formed of, for example, polysilicon including an impurity.

### Cap Portion

Returning to FIG. 4, the cap portion 54 will be described. The cap portion 54 is provided above the insulating core 51. The cap portion 54 is a semiconductor portion formed of a semiconductor material such as amorphous silicon or polysilicon. The cap portion 54 may be doped with an impurity. The cap portion 54 is provided on an inner peripheral side of an upper end portion of the channel layer 52, and is formed integrated with the channel layer 52. The cap portion 54 forms the upper end portion of the channel layer 52 and the upper end portion of the memory pillar 50. The memory pillar contact 70 is in contact in the Z direction with the cap portion 54.

### 3. 5 Memory Pillar Contact

Next, the memory pillar contact 70 will be described. The contact 70 is an electrical connecting portion that connects the memory pillar 50 and the bit line BL included in the upper wiring portion 90. When seen from above, the multiple of contacts 70 are disposed in positions corresponding to the multiple of memory pillars 50. Each contact 70 extends in the Z direction, and electrically connects the bit line BL and the cap portion 54 of the memory pillar 50.

### 3. 6 Conductive Layer Contact

Next, returning to FIG. 3, the conductive layer contact 80 will be described. The contact 80 is an electrical connecting portion that connects the conductive layer 31 and wiring 91 included in the upper wiring portion 90. The multiple of contacts 80 are provided in the first stepped region SR1 and the second stepped region SR2. The multiple of contacts 80 extend in the Z direction, and penetrate the multiple of conductive layers 31 and insulating layers 32. In the present embodiment, lengths in the Z direction of the multiple of contacts 80 are the same as each other. The multiple of contacts 80 extend, for example, below the lowest conductive layer 31. A configuration of the contact 80 will be described in detail hereafter.

### 3. 7 Upper Wiring Portion

Next, the upper wiring portion 90 will be described. The upper wiring portion 90 is disposed above the layered body 30. The upper wiring portion 90 includes, for example, the multiple of bit lines BL and a multiple of the wiring 91.

Each bit line BL is disposed on the corresponding memory pillar contact 70. The bit line BL is connected to the channel layer 52 of the memory pillar 50 via the contact 70. Because of this, any memory cell transistor MT can be selected from among the multiple of memory cell transistors MT disposed in a three-dimensional form by combining the word line WL and the bit line BL.

Each piece of wiring 91 is disposed on the corresponding conductive layer contact 80. The wiring 91 is connected to the conductive layer 31 (the word line WL, the drain side select gate line SGD, or the source side select gate line SGS) via the contact 80. Because of this, voltage can be applied to the desired conductive layer 31 by applying voltage to the wiring 91.

### 3. 8 Supporting Body

Next, the supporting body HR will be described. A multiple of the supporting body HR are, for example, provided in the first stepped region SR1 and the second stepped region SR2. The supporting body HR is a columnar body that extends in the Z direction inside the layered body 30. That is, each supporting body HR penetrates two or more conductive layers 31 and two or more insulating layers 32 included in the layered body 30 in the Z direction. The supporting body HR may, for example, be formed of an insulating material, and may have the same configuration as the memory pillar 50. The supporting body HR is a supporting portion that supports the multiple of insulating layers 32 in the first stepped region SR1 and the second stepped region SR2 in a state wherein a first sacrificial layer 131 is removed in a replacement process to be described hereafter. Only one portion of supporting bodies HR of the multiple of supporting bodies HR provided in the memory cell array 11 is shown in FIG. 3.

### 3. 9 Dividing Portion

Next, returning to FIG. 4, the dividing portion ST will be described. The dividing portion ST is a wall portion that divides the layered body 30 in the Y direction. A multiple of the dividing portion ST are disposed separated from each other in the Y direction (refer to FIG. 7). The dividing portion ST extends in the Z direction, and penetrates the layered body 30. Also, the dividing portion ST extends in such a way as to extend across the first stepped region SR1 and the second stepped region SR2 in the X direction, sandwiching the array region AR therebetween (refer to FIG. 7). The dividing portion ST includes, for example, an insulating portion STa and a conductive portion STb.

The insulating portion STa extends in the Z direction, and penetrates the layered body 30, the fourth semiconductor layer 25, the insulating layer 24, and the third semiconductor layer 23. The insulating portion STa divides each of the multiple of conductive layers 31 included in the layered body 30 in the Y direction. The insulating portion STa is formed of an insulating material such as silicon oxide.

The conductive portion STb is provided in an interior of the insulating portion STa. The conductive portion STb extends in the Z direction, and penetrates the layered body 30, the fourth semiconductor layer 25, the insulating layer 24, and the third semiconductor layer 23. A lower end of the conductive portion STb is connected to the source line SL. The conductive portion STb is formed of a conductive material such as tungsten. The conductive portion STb is an electrical connecting portion that connects the source line SL and wiring inside the memory cell array 11.

### 3. 10 Upper Dividing Portion

An upper dividing portion SHE is a dividing portion that is shallow in comparison with the dividing portion ST. A multiple of the upper dividing portion SHE are disposed separated in the Y direction (refer to FIG. 7). The upper dividing portion SHE is provided in an upper end portion of the layered body 30, and extends partway through the layered body 30 in the Z direction. The upper dividing portion SHE penetrates the conductive layer 31 functioning as the drain side select gate line SGD. Meanwhile, the upper dividing portion SHE does not reach the conductive layer 31 functioning as the word line WL. The upper dividing portion SHE is a wall portion that divides the conductive layer 31 functioning as the drain side select gate line SGD in the Y direction. The upper dividing portion SHE is formed of an insulating material such as silicon oxide. The upper dividing portion SHE extends in such a way as to extend over a whole length of the array region AR in the X direction.

FIG. 7 is a sectional view showing one portion of the memory cell array 11. In the present embodiment, the conductive layer 31 corresponding to the drain side select gate line SGD is divided in the Y direction by the dividing portion ST and the upper dividing portion SHE. Because of this, the drain side select gate line SGD extending in the X direction is formed. Because of this, a region partitioned by the dividing portion ST or the upper dividing portion SHE corresponds to one string unit SU.

### 4. Stepped Region Configuration

Next, a configuration of the stepped region SR will be described in detail.

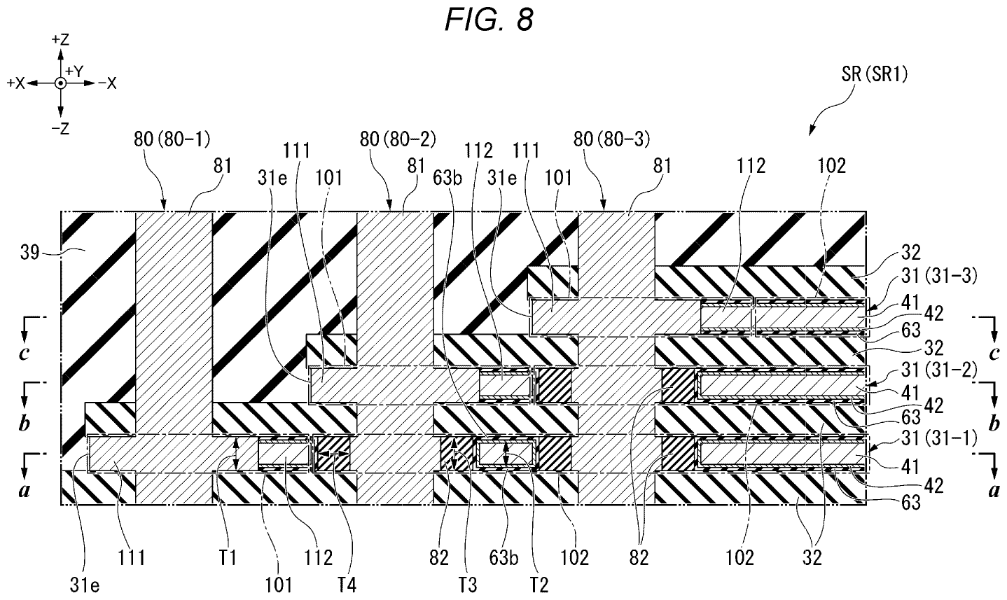

FIG. 8 is a sectional view wherein a region of the stepped region SR shown in FIG. 3 enclosed by an F8 line is shown enlarged. For ease of description, a configuration relating to three conductive layers 31 (first to third conductive layers 31-1 to 31-3) and three contacts 80 (first to third contacts 80-1 to 80-3) is extracted and shown in FIG. 8. A configuration of other conductive layers 31 and other contacts 80 is the same as the configuration to be described hereafter.

### 4. 1 Conductive Layer

In the present embodiment, the stepped region SR has, for example, the first conductive layer 31-1, the second conductive layer 31-2, and the third conductive layer 31-3 as the multiple of conductive layers 31 whose lengths in the X direction differ from each other. Although the first conductive layer 31-1, the second conductive layer 31-2, and the third conductive layer 31-3 are, for example, the conductive layer 31 that functions as the word line WL, the first conductive layer 31-1, the second conductive layer 31-2, and the third conductive layer 31-3 may also be the conductive layer 31 that functions as the drain side select gate line SGD or the source side select gate line SGS.

The first conductive layer 31-1 is positioned lowermost among the three conductive layers 31-1, 31-2, and 31-3. The first conductive layer 31-1 is one example of a “first gate electrode layer”.

The second conductive layer 31-2 is positioned medially among the three conductive layers 31-1, 31-2, and 31-3. In other words, the second conductive layer 31-2 is disposed on the +Z direction side with respect to the first conductive layer 31-1. A length in the X direction (for example, a length in the +X direction) of the second conductive layer 31-2 is less than a length in the X direction (for example, a length in the +X direction) of the first conductive layer 31-1. The second conductive layer 31-2 is one example of a “second gate electrode layer”.

The third conductive layer 31-3 is positioned uppermost among the three conductive layers 31-1, 31-2, and 31-3. In other words, the third conductive layer 31-3 is disposed on the +Z direction side with respect to the second conductive layer 31-2. A length in the X direction (for example, a length in the +X direction) of the third conductive layer 31-3 is less than a length in the X direction (for example, a length in the +X direction) of the second conductive layer 31-2. The third conductive layer 31-3 is one example of a “third gate electrode layer”.

### Terraced Portion and Non-Terraced Portion

Each conductive layer 31 has a terraced portion 101 and a non-terraced portion 102. The terraced portion 101 is a portion that does not coincide with another conductive layer 31 positioned on the +Z direction side when seen from the Z direction. The non-terraced portion 102 is a portion that coincides with another conductive layer 31 positioned on the +Z direction side when seen from the Z direction.

For example, the first conductive layer 31-1 has the terraced portion 101, which does not coincide with the second conductive layer 31-2, and the non-terraced portion 102, which coincides with the second conductive layer 31-2 when seen from the Z direction. In the same way, the second conductive layer 31-2 has the terraced portion 101, which does not coincide with the third conductive layer 31-3, and the non-terraced portion 102, which coincides with the third conductive layer 31-3 when seen from the Z direction.

In the present embodiment, a thickness T1 in the Z direction of the terraced portion 101 is the same as a thickness T2 in the Z direction of the non-terraced portion 102. In the present application, “a thickness in the Z direction of a terraced portion and a thickness in the Z direction of a non-terraced portion are the same”, not being limited to a case wherein the thickness T1 in the Z direction of the terraced portion 101 and the thickness T2 in the Z direction of the non-terraced portion 102 coincide perfectly, means the thickness T1 in the Z direction of the terraced portion 101 and the thickness T2 in the Z direction of the non-terraced portion 102 are within a range wherein the two can be regarded as being the same.

For example, a case wherein, for a manufacturing related reason, the thickness T2 in the Z direction of the non-terraced portion 102 is small in comparison with the thickness T1 in the Z direction of the terraced portion 101 corresponds to one example of a case wherein “a thickness in the Z direction of a terraced portion and a thickness in the Z direction of a non-terraced portion are the same”. For example, a case wherein the thickness T2 in the Z direction of the non-terraced portion 102 is small in comparison with the thickness T1 in the Z direction of the terraced portion 101 because the second portion 63b of the block insulating film 63 exists between the conductive layer 31 and the insulating layer 32 corresponds to one example of a case wherein “a thickness in the Z direction of a terraced portion and a thickness in the Z direction of a non-terraced portion are the same”. In the present application, “a thickness in the Z direction of a terraced portion and a thickness in the Z direction of a non-terraced portion are the same” broadly means a case wherein a process of intentionally increasing the thickness in the Z direction of the terraced portion 101 in comparison with the thickness T2 in the Z direction of the non-terraced portion 102 (for example, an additional stacking process) does not exist.

The “thickness T1 in the Z direction of the terraced portion 101” is, for example, a thickness in the Z direction of the terraced portion 101 in a position between the contact 80 connected to the conductive layer 31 including the relevant terraced portion 101 and the contact 80 connected to the conductive layer 31 one to the upper side with respect to the conductive layer 31 including the relevant terraced portion 101. For example, the “thickness T1 in the Z direction of the terraced portion 101 of the first conductive layer 31-1” is a thickness in the Z direction of the terraced portion 101 in a position between the first contact 80-1 and the second contact 80-2, to be described hereafter.

The “thickness T2 in the Z direction of the non-terraced portion 102” is, for example, a thickness in the Z direction of the non-terraced portion 102 in a position between the contact 80 connected to another conductive layer 31 one to the upper side with respect to the conductive layer 31 including the relevant non-terraced portion 102 and the contact 80 connected to another conductive layer 31 two to the upper side with respect to the conductive layer 31 including the relevant non-terraced portion 102. For example, the “thickness T2 in the Z direction of the non-terraced portion 102 of the first conductive layer 31-1” is a thickness in the Z direction of the non-terraced portion 102 in a position between the second contact 80-2 and the third contact 80-3, to be described hereafter.

Also, from another perspective, the thickness T1 in the Z direction of the terraced portion 101 is the same as a thickness T3 in the Z direction of an insulating portion 82, to be described hereafter, provided at the same height as the relevant terraced portion 101. In the present application, “a thickness in the Z direction of a terraced portion and a thickness in the Z direction of an insulating portion are the same”, not being limited to a case wherein the thickness T1 in the Z direction of the terraced portion 101 and the thickness T3 in the Z direction of the insulating portion 82 coincide perfectly, means the thickness T1 in the Z direction of the terraced portion 101 and the thickness T3 in the Z direction of the insulating portion 82 are within a range wherein the two can be regarded as being the same. In the present application, “a thickness in the Z direction of a terraced portion and a thickness in the Z direction of an insulating portion are the same” broadly means a case wherein a process of intentionally increasing the thickness in the Z direction of the terraced portion 101 in comparison with the thickness T3 in the Z direction of the insulating portion 82 (for example, an additional stacking process) does not exist.

The “insulating portion 82 provided at the same height as the terraced portion 101” is, for example, the insulating portion 82 provided in the contact 80 connected to the conductive layer 31 one to the upper side with respect to the conductive layer 31 including the relevant terraced portion 101. For example, the “insulating portion 82 provided at the same height as the terraced portion 101 of the first conductive layer 31-1” is the insulating portion 82 provided in the second contact 80-2, to be described hereafter.

### Terraced Replacement Formation Portion and Normal Formation Portion

Next, a terraced replacement formation portion 111 and a normal formation portion 112 will be described. In the present embodiment, the terraced portion 101 has the terraced replacement formation portion (a first portion) 111 and the normal formation portion (a second portion) 112.

The terraced replacement formation portion 111 is a portion formed using a replacement process differing from the greater portion of the conductive layer 31. The terraced replacement formation portion 111 is an end portion on the X direction side (for example, the +X direction side) of the conductive layer 31, and includes an end 31e on the X direction side (for example, an end on the +X direction side) of the conductive layer 31. The terraced replacement formation portion 111 is positioned on a side in the X direction opposite to that of the non-terraced portion 102 with respect to an end 42e in the X direction of the barrier metal film 42, to be described hereafter.

The terraced replacement formation portion 111 is, for example, formed integrated with a conductive portion 81 of the contact 80 using a replacement process to be described hereafter. The terraced replacement formation portion 111 is formed of the same conductive material (for example, a metal material such as tungsten or molybdenum) as the conductive portion 81 of the contact 80. The terraced replacement formation portion 111 does not have the barrier metal film 42. The terraced replacement formation portion 111 is formed of a single layer (for example, a single metal layer). Also, the block insulating film 63 does not exist between the terraced replacement formation portion 111 and the insulating layer 32. The terraced replacement formation portion 111 is formed in a strip form in the Y direction. The terraced replacement formation portion 111 is in contact with the normal formation portion 112 in the X direction, and is electrically connected to the normal formation portion 112. The terraced replacement formation portion 111 is one example of each of a “conductive portion” and a “metal portion”.

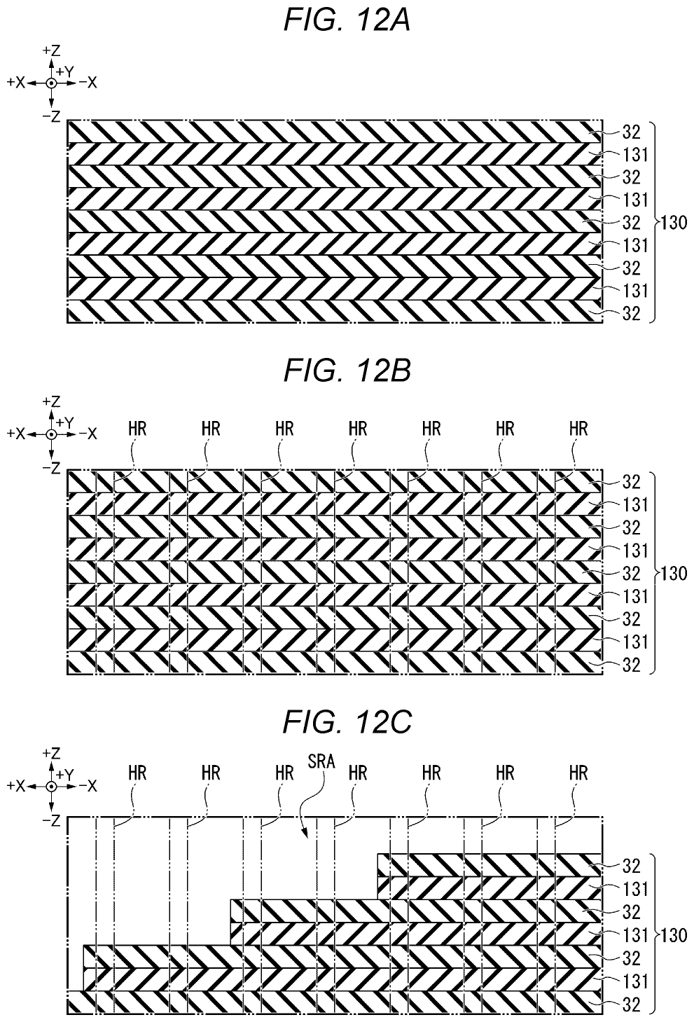

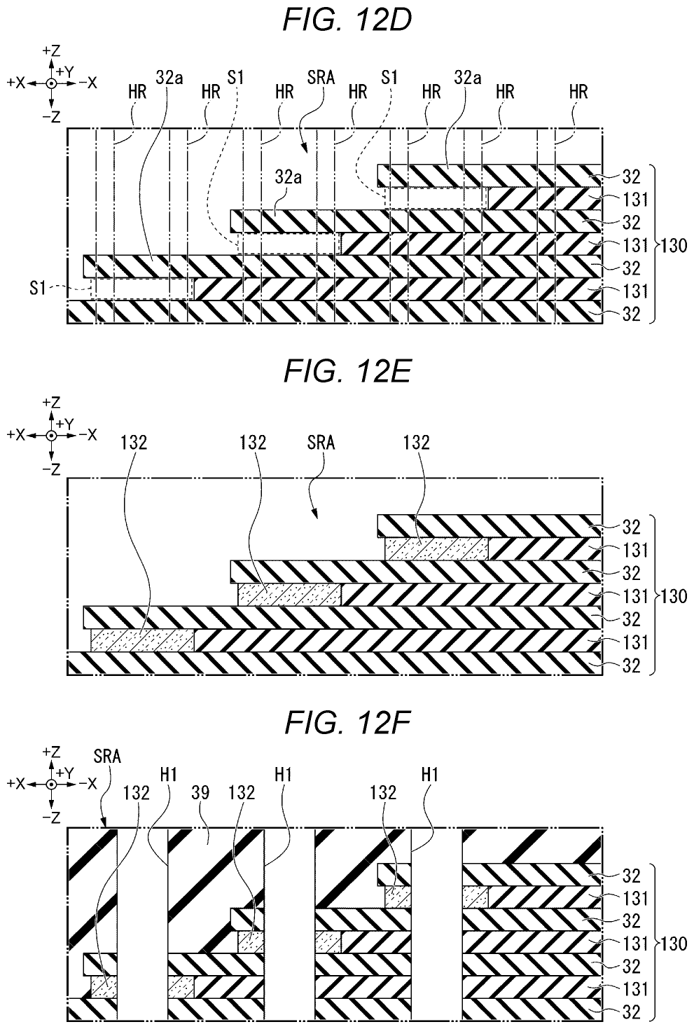

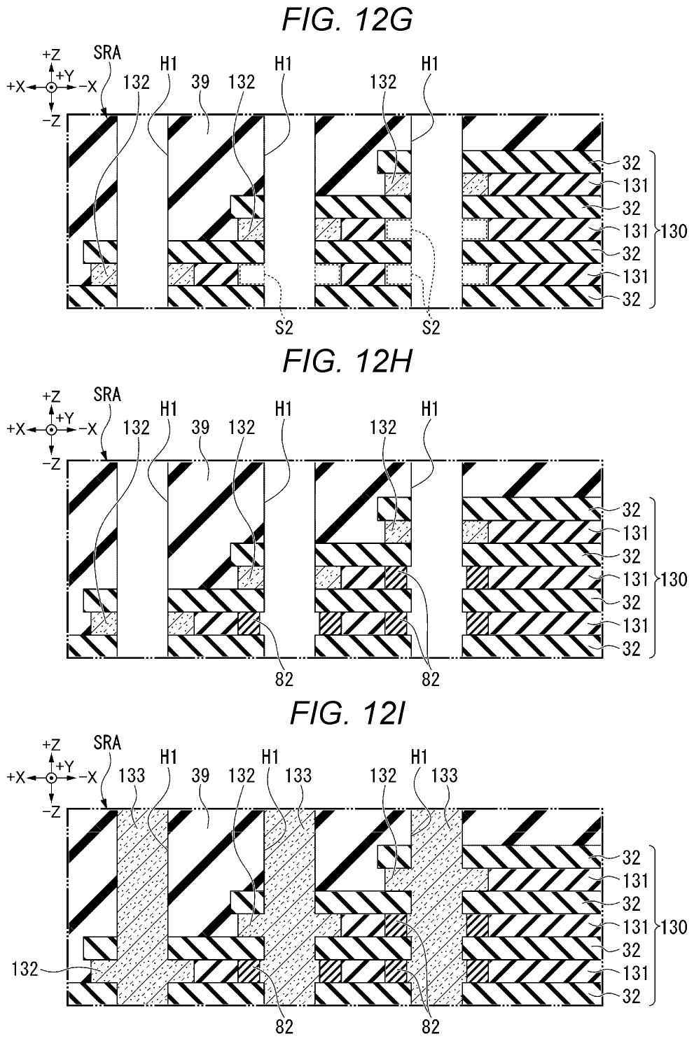

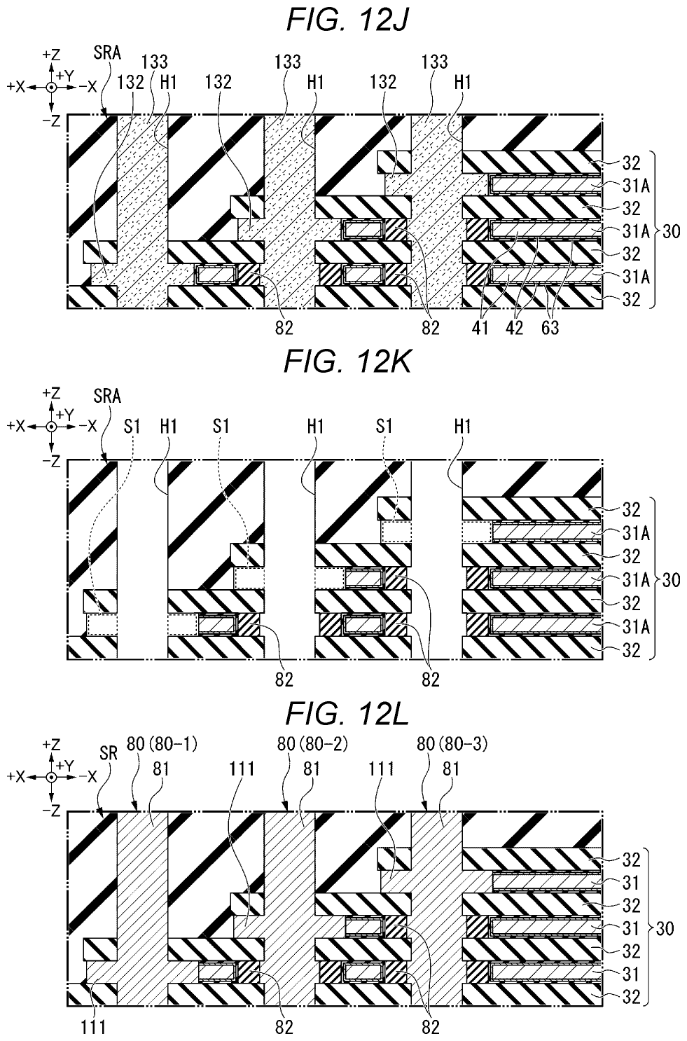

In the present embodiment, at least one portion of supporting bodies HR of the multiple of supporting bodies HR is provided in the terraced replacement formation portion 111. The supporting body HR supports the insulating layer 32 in such a way as to restrict warping of the insulating layer 32 positioned above the terraced replacement formation portion 111 when manufacturing the terraced replacement formation portion 111 (refer to FIG. 12D).

The normal formation portion 112 is a portion formed using the same replacement process as the greater portion of the conductive layer 31. The normal formation portion 112 is provided between the terraced replacement formation portion 111 and the non-terraced portion 102 in the X direction. The normal formation portion 112 is positioned in the X direction between the end 42e in the X direction of the barrier metal film 42, to be described hereafter, and the non-terraced portion 102.

The normal formation portion 112 is formed integrated with the non-terraced portion 102. The normal formation portion 112 has the same configuration as the non-terraced portion 102. For example, the normal formation portion 112 includes the conductive layer main body 41 and the barrier metal film 42. In the present embodiment, the second portion 63b of the block insulating film 63 exists between the normal formation portion 112 and the insulating layer 32.

### 4. 2 Conductive Layer Contact

In the present embodiment, the multiple of contacts 80 include the first contact 80-1, the second contact 80-2, and the third contact 80-3.

The first contact 80-1 is provided corresponding to the terraced portion 101 of the first conductive layer 31-1. The first contact 80-1 is electrically connected to the terraced portion 101 of the first conductive layer 31-1. The first contact 80-1 is one example of a “first columnar body”.

The second contact 80-2 is provided corresponding to the terraced portion 101 of the second conductive layer 31-2, and is electrically connected to the terraced portion 101 of the second conductive layer 31-2. The second contact 80-2 is one example of a “second columnar body”.

The third contact 80-3 is provided corresponding to the terraced portion 101 of the third conductive layer 31-3, and is electrically connected to the terraced portion 101 of the third conductive layer 31-3. The third contact 80-3 is one example of a “third columnar body”.

### Conductive Portion and Insulating Portion

Each contact 80 has, for example, the conductive portion 81 and one or more (for example, a multiple of) insulating portions 82.

When seen from the Z direction, the conductive portion 81 is provided in a position coinciding with the terraced portion 101 of the conductive layer 31 that is a connection destination. The conductive portion 81 extends in the Z direction, and penetrates the terraced portion 101 of the conductive layer 31 that is a connection destination in the Z direction. For example, the conductive portion 81 penetrates the terraced replacement formation portion 111 in the terraced portion 101 of the conductive layer 31 that is a connection destination in the Z direction, and is connected to the terraced replacement formation portion 111. The insulating portion 82 does not exist between the conductive layer 31 that is a connection destination and the conductive portion 81. The conductive portion 81 is connected to the terraced replacement formation portion 111 of the conductive layer 31 that is a connection destination, and thereby electrically connected to the conductive layer 31 that is a connection destination.

Also, the conductive portion 81 penetrates the non-terraced portion 102 of the multiple of conductive layers 31 that are not connection destinations (the non-terraced portion 102 of the multiple of conductive layers 31 positioned below the conductive layer 31 that is a connection destination) and the multiple of insulating layers 32 in the Z direction. The conductive portion 81 is formed of, for example, a conductive material (for example, a metal material) such as tungsten or molybdenum. The conductive portion 81 is one example of a “metal portion”.

The multiple of insulating portions 82 are disposed separately at the same height as the multiple of conductive layers 31 that are not connection destinations (the multiple of conductive layers 31 positioned below the conductive layer 31 that is a connection destination). Each insulating portion 82 is formed in a ring form enclosing the conductive portion 81 at the same height as the conductive layer 31 that is not a connection destination. Each insulating portion 82 is provided between the conductive layer 31 that is not a connection destination and the conductive portion 81, and electrically isolates the conductive layer 31 that is not a connection destination and the conductive portion 81. The insulating portion 82 is formed of, for example, an insulating material such as silicon oxide. A thickness T4 in the X direction of the insulating portion 82 (for example, a thickness of a smallest portion) is 20 nm or greater.

For example, the conductive portion 81 of the first contact 80-1 penetrates the terraced portion 101 of the first conductive layer 31-1 in the Z direction, and is electrically connected to the first conductive layer 31-1. The conductive portion 81 of the first contact 80-1 penetrates the non-terraced portion 102 of the multiple of conductive layers 31 that are not connection destinations positioned lower than the first conductive layer 31-1 in the Z direction. The multiple of insulating portions 82 of the first contact 80-1 are disposed between the non-terraced portion 102 of the multiple of conductive layers 31 that are not connection destinations positioned lower than the first conductive layer 31-1 and the conductive portion 81 of the first contact 80-1. The conductive portion 81 of the first contact 80-1 is one example of a “first conductive portion”.

The conductive portion 81 of the second contact 80-2 penetrates the terraced portion 101 of the second conductive layer 31-2 in the Z direction, and is electrically connected to the second conductive layer 31-2. The conductive portion 81 of the second contact 80-2 penetrates the non-terraced portion 102 of the multiple of conductive layers 31 that are not connection destinations positioned lower than the second conductive layer 31-2 (for example, the first conductive layer 31-1) in the Z direction. The multiple of insulating portions 82 of the second contact 80-2 are disposed between the non-terraced portion 102 of the multiple of conductive layers 31 that are not connection destinations positioned lower than the second conductive layer 31-2 and the conductive portion 81 of the second contact 80-2. The conductive portion 81 of the second contact 80-2 is one example of a “second conductive portion”.

The conductive portion 81 of the third contact 80-3 penetrates the terraced portion 101 of the third conductive layer 31-3 in the Z direction, and is electrically connected to the third conductive layer 31-3. The conductive portion 81 of the third contact 80-3 penetrates the non-terraced portion 102 of the multiple of conductive layers 31 that are not connection destinations positioned lower than the third conductive layer 31-3 (for example, the first conductive layer 31-1 and the second conductive layer 31-2) in the Z direction. The multiple of insulating portions 82 of the third contact 80-3 are disposed between the non-terraced portion 102 of the multiple of conductive layers 31 that are not connection destinations positioned lower than the third conductive layer 31-3 and the conductive portion 81 of the third contact 80-3. The conductive portion 81 of the third contact 80-3 is one example of a “third conductive portion”.

### 4. 3 Barrier Metal Film Form

Next, a form of the barrier metal film 42 will be described.

As shown in FIG. 8, the barrier metal film 42 is provided in the stepped region SR at least between the conductive layer main body 41 and the insulating layer 32 positioned on the upper side of the relevant conductive layer main body 41 (for example, between the conductive layer main body 41 and the block insulating film 63 positioned on the upper side of the relevant conductive layer main body 41) and between the conductive layer main body 41 and the insulating layer 32 positioned on the lower side of the relevant conductive layer main body 41 (for example, between the conductive layer main body 41 and the block insulating film 63 positioned on the lower side of the relevant conductive layer main body 41).

In the present embodiment, the barrier metal film 42 and the block insulating film 63 do not exist on a boundary between the terraced replacement formation portion 111 and the normal formation portion 112 (an interface between the terraced replacement formation portion 111 and the normal formation portion 112). This kind of configuration is formed by, for example, the block insulating film 63 and the barrier metal film 42 positioned on an end of the normal formation portion 112 being removed simultaneously in a process wherein a sacrificial body 133 replaced by the contact 80 and the terraced replacement formation portion 111 is removed by etching (refer to FIG. 12K).

Meanwhile, the barrier metal film 42 may exist on the boundary between the terraced replacement formation portion 111 and the normal formation portion 112 (the interface between the terraced replacement formation portion 111 and the normal formation portion 112). This kind of configuration is formed by, for example, only the block insulating film 63 positioned on the end of the normal formation portion 112 being removed and the barrier metal film 42 being left in the process wherein the sacrificial body 133 replaced by the contact 80 and the terraced replacement formation portion 111 is removed by etching.

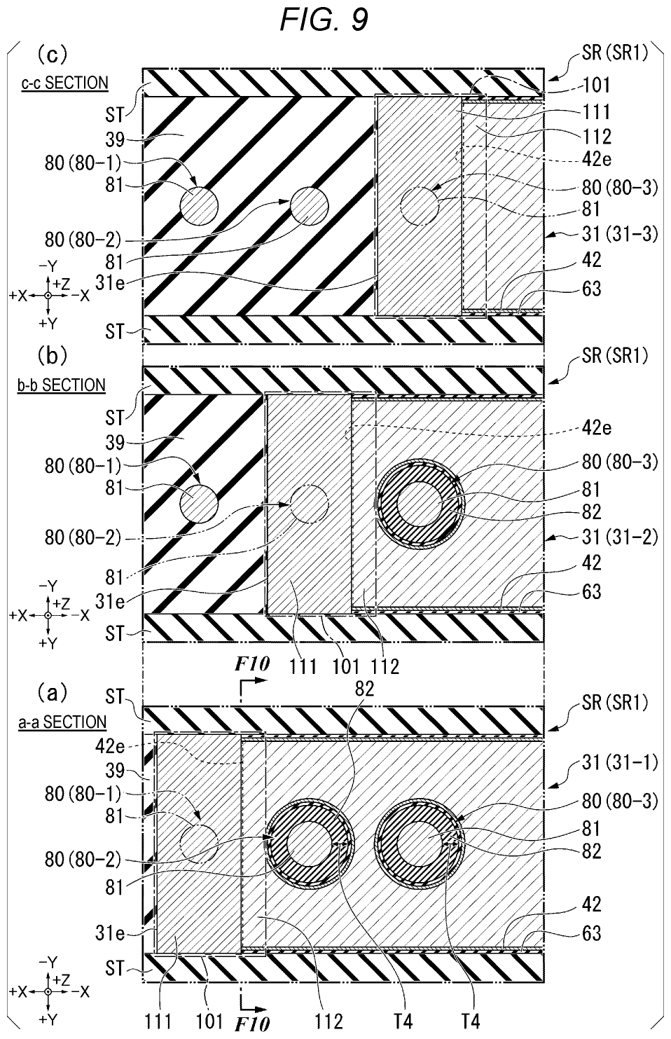

FIG. 9 is a sectional view of one portion of the stepped region SR. For example, the end 42e in the X direction of the barrier metal film 42 provided in the first conductive layer 31-1 is positioned on the boundary between the terraced replacement formation portion 111 of the first conductive layer 31-1 and the normal formation portion 112. At least one portion (all portions in the present embodiment) of the end 42e in the X direction of the barrier metal film 42 provided in the first conductive layer 31-1 is positioned, with regard to the X direction, between the conductive portion 81 of the first contact 80-1 and the conductive portion 81 of the second contact 80-2, and extends linearly in the Y direction.

In the same way, the end 42e in the X direction of the barrier metal film 42 provided in the second conductive layer 31-2 is positioned on the boundary between the terraced replacement formation portion 111 of the second conductive layer 31-2 and the normal formation portion 112. At least one portion (all portions in the present embodiment) of the end 42e in the X direction of the barrier metal film 42 provided in the second conductive layer 31-2 is positioned between the conductive portion 81 of the second contact 80-2 and the conductive portion 81 of the third contact 80-3, and extends linearly in the Y direction. The same applies to other conductive layers 31.

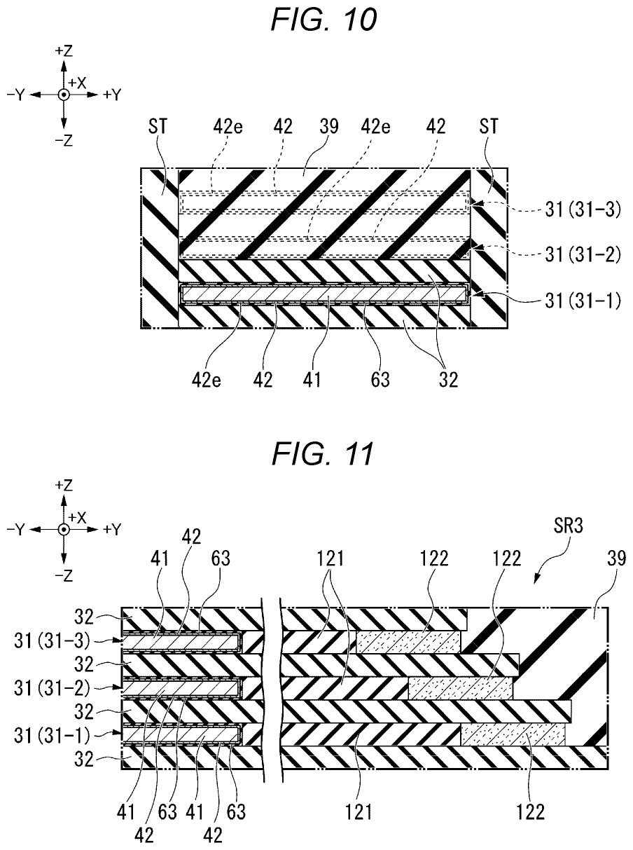

FIG. 10 is a sectional view along an F10-F10 line of the stepped region SR shown in FIG. 9. As heretofore described, the end 42e in the X direction of the barrier metal film 42 provided in the first conductive layer 31-1 extends linearly in the Y direction. The end 42e in the X direction of the barrier metal film 42 provided in the second conductive layer 31-2 extends linearly in the Y direction.

### 4. 4 Dummy Stepped Region Structure

Next, a dummy stepped region SR3 will be described.

The dummy stepped region SR3 is a region formed in both end portions in the Y direction of the array region AR in accompaniment to a formation of the first stepped region SR1 and the second stepped region SR2 (refer to FIG. 7).

FIG. 11 is a sectional view along an F11-F11 line of the dummy stepped region SR3 shown in FIG. 7. The dummy stepped region SR3 is a region wherein lengths in the Y direction of the multiple of insulating layers 32 differ. In the dummy stepped region SR3, the multiple of insulating layers 32 are such that the length in the Y direction is greater the farther downward the insulating layer 32 is positioned.

In the present embodiment, an end portion in the Y direction of the dummy stepped region SR3 has a multiple of insulating layers 121 and a multiple of semiconductor layers 122.

The multiple of insulating layers 121 are disposed separately at the same height as the multiple of conductive layers 31. The insulating layer 121 is disposed between two insulating layers 32, in the same way as the conductive layer 31, and is aligned with the conductive layer 31 in the Y direction. The insulating layer 121 extends in the X direction between two insulating layers 32. The insulating layer 121 extends, for example, over the whole length of the array region AR in the X direction.

The insulating layer 121 is an insulating layer formed by one portion (for example, an end portion in the Y direction) of the first sacrificial layer 131 provided in a layered body 130 partway through manufacture, to be described hereafter, remaining without being replaced by the conductive layer 31. The insulating layer 121 is formed of, for example, an insulating material such as silicon nitride. The insulating layer 121 is one example of a “second insulating layer”. The insulating layer 121 need not exist. In this case, the conductive layer 31 and the semiconductor layer 122 neighbor in the Y direction.

The multiple of semiconductor layers 122 are disposed separately at the same height as the multiple of conductive layers 31. The semiconductor layer 122 is disposed between two insulating layers 32, in the same way as the conductive layer 31, and is aligned with the conductive layer 31 in the Y direction. The semiconductor layer 122 is disposed on a side of the insulating layer 121 opposite to that of the conductive layer 31. The semiconductor layer 122 extends in the X direction between two insulating layers 32. The semiconductor layer 122 extends, for example, over the whole length of the array region AR in the X direction.

The semiconductor layer 122 is a semiconductor layer formed by one portion (for example, an end portion in the Y direction) of a second sacrificial layer 132 provided in the layered body 130 partway through manufacture, to be described hereafter, remaining without being replaced by the terraced replacement formation portion 111. The semiconductor layer 122 is formed of, for example, a semiconductor material such as amorphous silicon.

### 5. Manufacturing Method

Next, a method of manufacturing the semiconductor storage device 1 will be described.

FIGS. 12A to 12L are sectional views illustrating a method of manufacturing the semiconductor storage device 1. Hereafter, the description will be given centered on a portion relating to a formation of the stepped region SR. Other portions of the semiconductor storage device 1 can be formed using, for example, a publicly known method.

Firstly, as shown in FIG. 12A, the layered body 130 is formed by one each of the first sacrificial layer 131 and the insulating layer 32 being stacked alternately in the Z direction on a lower structure partway through manufacture. The layered body 130 includes a multiple of the first sacrificial layer 131 and a multiple of the insulating layer 32. The first sacrificial layer 131 is a layer replaced by the conductive layer 31 in a replacement process to be described hereafter. The first sacrificial layer 131 is formed of, for example, an insulating material such as silicon nitride.

Next, as shown in FIG. 12B, the multiple of supporting bodies HR are formed in the layered body 130. For example, a multiple of holes following the Z direction are formed in the layered body 130, and the supporting body HR is formed by a material of the supporting body HR being supplied to an interior of the multiple of holes.

Next, as shown in FIG. 12C, an end portion region of the layered body 130, which becomes the stepped region SR in a subsequent process, is formed in stepped form. For example, the end portion region of the layered body 130 is formed in stepped form by providing an unshown resist layer, and repeatedly carrying out a slimming of the resist layer using an isotropic etching, and carrying out an anisotropic etching of the layered body 130 using the resist layer on which the slimming is carried out. By so doing, a stepped region SRA wherein lengths in the X direction of the multiple of first sacrificial layers 131 differ is formed.

Next, as shown in FIG. 12D, end portions in the X direction and the Y direction of the multiple of first sacrificial layers 131 are removed by carrying out a wet etching on the stepped region SRA using an etchant such that selectivity of the first sacrificial layer 131 with respect to the insulating layer 32 is high. The aforementioned etchant is, for example, a solution including hot phosphoric acid (H₃PO₄). By so doing, a multiple of first space portions S1 corresponding to the removed end portions of the multiple of first sacrificial layers 131 are formed in end portions in the X direction and the Y direction of the layered body 130. Each first space portion S1 is positioned between a multiple of the insulating layer 32.

In the present embodiment, the supporting body HR is also formed in an end portion 32a in the insulating layer 32 positioned above the first space portion S1, and the end portion 32a is supported by the supporting body HR. Because of this, warping of the end portion 32a of the insulating layer 32 when the first space portion S1 is formed is restricted. To facilitate viewing of the drawings, a depiction of the supporting body HR is omitted from FIG. 12E onward.

Next, as shown in FIG. 12E, a multiple of the second sacrificial layer 132 are formed in the multiple of first space portions S1. That is, sacrificial bodies are provided in such a way as to fill the multiple of first space portions S1, and the multiple of second sacrificial layers 132 are formed by an unneeded portion of the sacrificial body being removed by etching or the like. The second sacrificial layer 132 is formed of, for example, a semiconductor material such as amorphous silicon.

Next, as shown in FIG. 12F, the insulating portion 39 is provided in such a way as to cover the stepped region SRA. Next, a multiple of holes H1 are provided in the stepped region SRA in such a way as to penetrate the insulating portion 39 and the stepped region SRA in the Z direction. The multiple of holes H1 penetrate the second sacrificial layer 132, the multiple of first sacrificial layers 131, and the multiple of insulating layers 32 in the Z direction.

Next, as shown in FIG. 12G, etching is carried out through the multiple of holes H1 by supplying an etchant to the multiple of holes H1. By so doing, one portion of the multiple of first sacrificial layers 131 exposed in the multiple of holes H1 is removed. Because of this, a multiple of second space portions S2 corresponding to the removed one portion of the multiple of first sacrificial layers 131 are formed among the multiple of insulating layers 32. Herein, the second sacrificial layer 132 remains without being removed owing to an etchant such that selectivity of the first sacrificial layer 131 with respect to the second sacrificial layer 132 is high being used as the aforementioned etchant. The etchant is, for example, a solution including hot phosphoric acid (H₃PO₄).

Next, as shown in FIG. 12H, the multiple of insulating portions 82 are formed in the multiple of second space portions S2. That is, insulating bodies are provided in such a way as to fill the multiple of second space portions S2, and the multiple of insulating portions 82 are formed by an unneeded portion of the insulating body being removed by etching.

Next, as shown in FIG. 12I, the sacrificial body 133 is formed in such a way as to fill the multiple of holes H1. The sacrificial body 133 is formed of, for example, the same material as the second sacrificial layer 132. That is, the sacrificial body 133 is formed of, for example, a semiconductor material such as amorphous silicon.

Next, as shown in FIG. 12J, the multiple of first sacrificial layers 131 are replaced with a conductive layer 31A in a state wherein a multiple of the sacrificial body 133 are provided in the multiple of holes H1. That is, for example, an unshown groove for forming the dividing portion ST is formed in the layered body 130, and the multiple of first sacrificial layers 131 are removed by an etchant being supplied to the groove. Further, materials of the block insulating film 63, the barrier metal film 42, and the conductive layer main body 41 are supplied sequentially to spaces from which the multiple of first sacrificial layers 131 are removed, whereby the block insulating film 63 and the conductive layer 31A are formed among the multiple of insulating layers 32. The conductive layer 31A is a portion of the conductive layer 31 excepting the terraced replacement formation portion 111, to be described hereafter.

Next, as shown in FIG. 12K, the multiple of second sacrificial layers 132 and the multiple of sacrificial bodies 133 are removed by, for example, wet etching. Because of this, the multiple of holes H1 and the multiple of first space portions S1 reappear.

Next, as shown in FIG. 12L, a metal material such as tungsten or molybdenum is supplied to the multiple of first space portions S1 and the multiple of holes H1. By so doing, the terraced replacement formation portion 111 of the multiple of conductive layers 31 is formed in the multiple of first space portions S1, and the conductive portion 81 of the multiple of contacts 80 is formed in the multiple of holes H1. That is, the multiple of second sacrificial layers 132 are replaced with one portion (the terraced replacement formation portion 111) of the multiple of conductive layers 31, and the multiple of sacrificial bodies 133 are replaced with the multiple of conductive portions 81. Because of this, the stepped region SR is completed.

The heretofore described manufacturing method is such that in order to restrict warping of the end portion 32a of the insulating layer 32 when an end portion of the sacrificial layer 131 existing in the stepped region SRA is removed, the multiple of supporting bodies HR are formed in the layered body 130 before the stepped region SRA is formed. A method of manufacturing the semiconductor storage device 1 is not limited to the heretofore described example. For example, the stepped region SRA may be formed first, and the multiple of supporting bodies HR may be formed after carrying out a process of removing an end portion of the sacrificial layer 131, or the like. In this case, a length in the X direction of an end portion of the sacrificial layer 131 removed from the stepped region SRA is preferably reduced.

### 6. Advantages

A configuration wherein lengths in the Z direction of a multiple of contacts are changed in such a way as to correspond to heights of a multiple of terraced portions formed in a stepped form will be considered as a first comparative example. This kind of configuration is such that the greater the number of layers of the layered body 30, the more processing difficulty increases. For example, position adjustment in the Z direction in a contact hole processing becomes difficult, and formation of a deep hole that penetrates a terraced portion that is a connection destination, or formation of a shallow hole that does not reach a terraced portion that is a connection destination, may occur. Because of this, there is room for improvement in terms of reliability and yield.

In the present embodiment, the first contact 80-1 includes the conductive portion 81, which penetrates the first conductive layer 31-1 in the Z direction and is electrically connected to the first conductive layer 31-1. The second contact 80-2 includes the conductive portion 81, which penetrates the second conductive layer 31-2 and the first conductive layer 31-1 in the Z direction and is electrically connected to the second conductive layer 31-2, and the insulating portion 82 disposed between the first conductive layer 31-1 and the conductive portion 81. According to this kind of configuration, an electrical connection between the contact 80 and the conductive layer 31 is ensured, and a simplification of position adjustment in the Z direction in a contact hole processing can be achieved. Because of this, an improvement in reliability and yield can be achieved.

A configuration wherein a terraced portion is formed to be thicker in comparison with a non-terraced portion by carrying out an additional stacking process on the terraced portion, and the terraced portion and a contact are formed integrated, will be considered as a second comparative example. This kind of configuration is such that there is a possibility of excessive etching occurring in the thickly formed terraced portion in a replacement process relating to the thickly formed terraced portion, and there is a possibility of a decrease in an inter-conductive layer breakdown voltage level, or the like, occurring.

Meanwhile, in the present embodiment, the thickness T1 in the Z direction of the terraced portion 101 of the conductive layer 31 and the thickness T2 in the Z direction of the non-terraced portion 102 of the conductive layer 31 are the same. This kind of configuration is such that there is little possibility of excessive etching occurring in a terraced portion in a replacement process relating to the terraced portion, and electrical properties can be maintained well. Because of this, a further improvement in reliability and yield can be achieved.

### 7. Modifications

Next, some modifications of the first embodiment will be described. Configurations of each modification other than those described hereafter are the same as the configurations of the first embodiment.

### 7. 1 First Modification

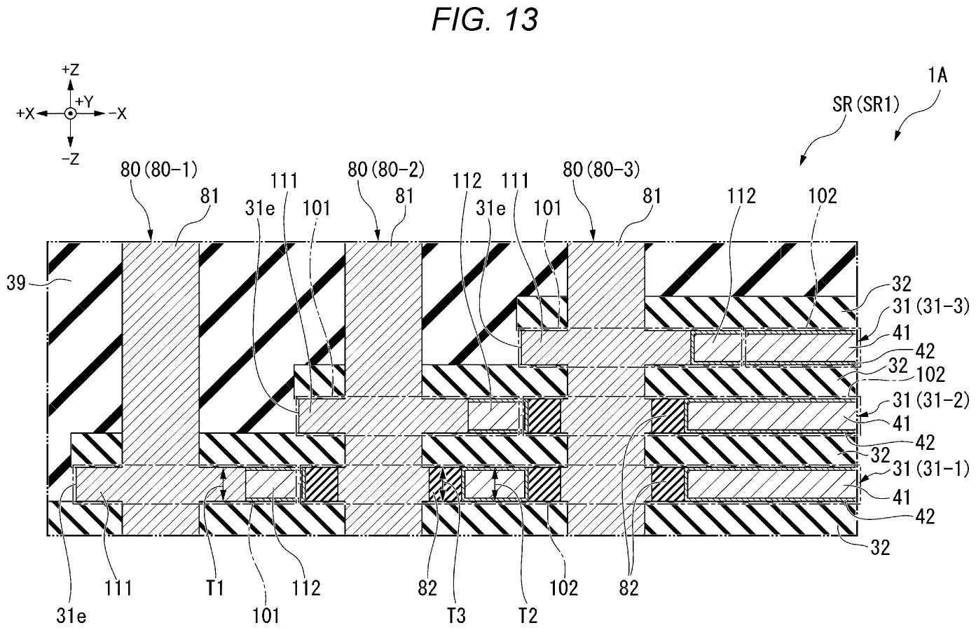

FIG. 13 is a sectional view showing one portion of a semiconductor storage device 1A of a first modification of the first embodiment. In the heretofore described embodiment, one portion of the block insulating film 63 is provided between the conductive layer 31 and the insulating layer 32. Meanwhile, the present modification is such that the block insulating film 63 is provided on an inner peripheral face of a through hole for forming the memory pillar 50. Because of this, the block insulating film 63 is formed in a ring form as one portion of the memory film 53, extends in the Z direction, and does not exist between the conductive layer 31 and the insulating layer 32. The present modification is also such that the thickness T1 in the Z direction of the terraced portion 101 of the conductive layer 31 and the thickness T2 of the non-terraced portion 102 of the conductive layer 31 are the same.

### 7. 2 Second Modification

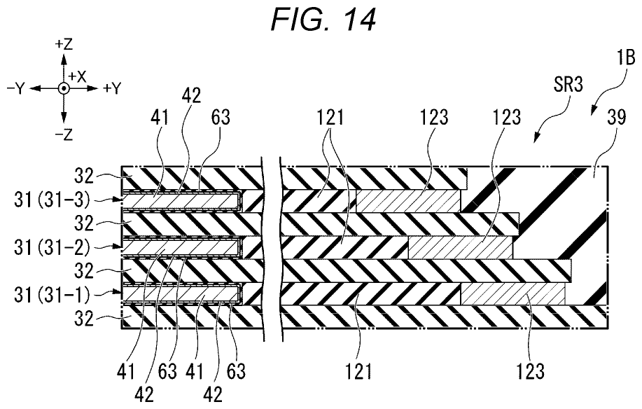

FIG. 14 is a sectional view showing one portion of a semiconductor storage device 1B of a second modification of the first embodiment. In the heretofore described embodiment, one portion of the block insulating film 63 in which the semiconductor layer 122 including amorphous silicon is provided is provided between the conductive layer 31 and the insulating layer 32 in an end portion in the Y direction of the layered body 30. Meanwhile, the present modification is such that a metal layer 123 is provided in an end portion in the Y direction of the layered body 30.

A multiple of the metal layer 123 are disposed separately at the same height as the multiple of conductive layers 31. The metal layer 123 is disposed between two insulating layers 32, in the same way as the conductive layer 31, and is aligned with the conductive layer 31 in the Y direction. The metal layer 123 is disposed on a side of the insulating layer 121 opposite to that of the conductive layer 31. The metal layer 123 extends in the X direction between two insulating layers 32. The metal layer 123 extends, for example, over the whole length of the array region AR in the X direction.

The metal layer 123 is a metal layer incidentally formed in an end portion in the Y direction of the layered body 130 in accompaniment to forming the terraced replacement formation portion 111 using a manufacturing method of a modification to be described hereafter. The metal layer 123, for example, is formed by the same material as the terraced replacement formation portion 111.

### Manufacturing Method

Next, a method of manufacturing the semiconductor storage device 1B will be described.

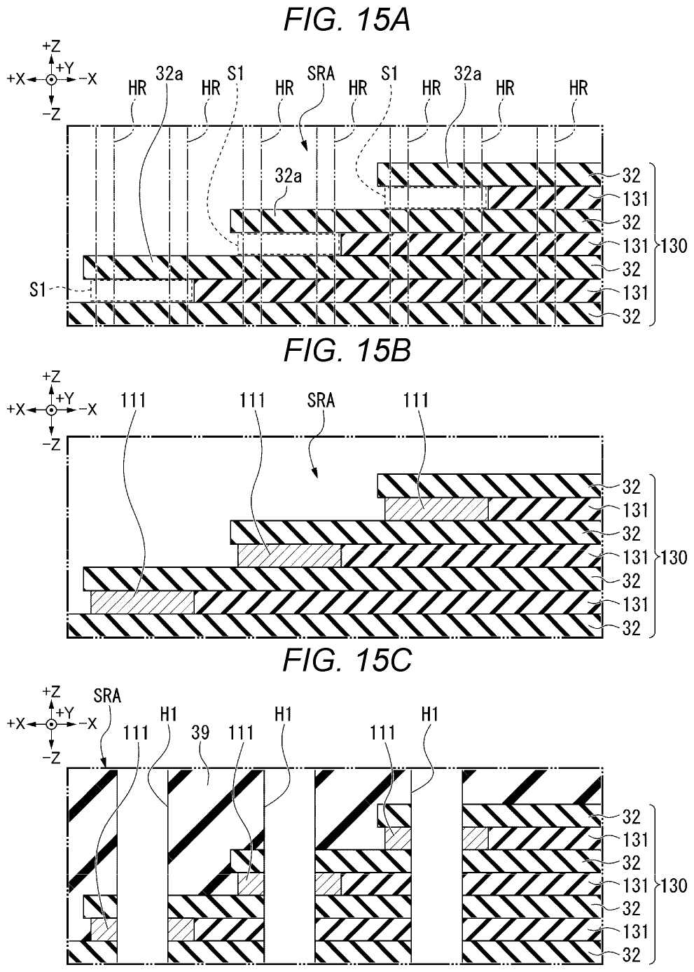

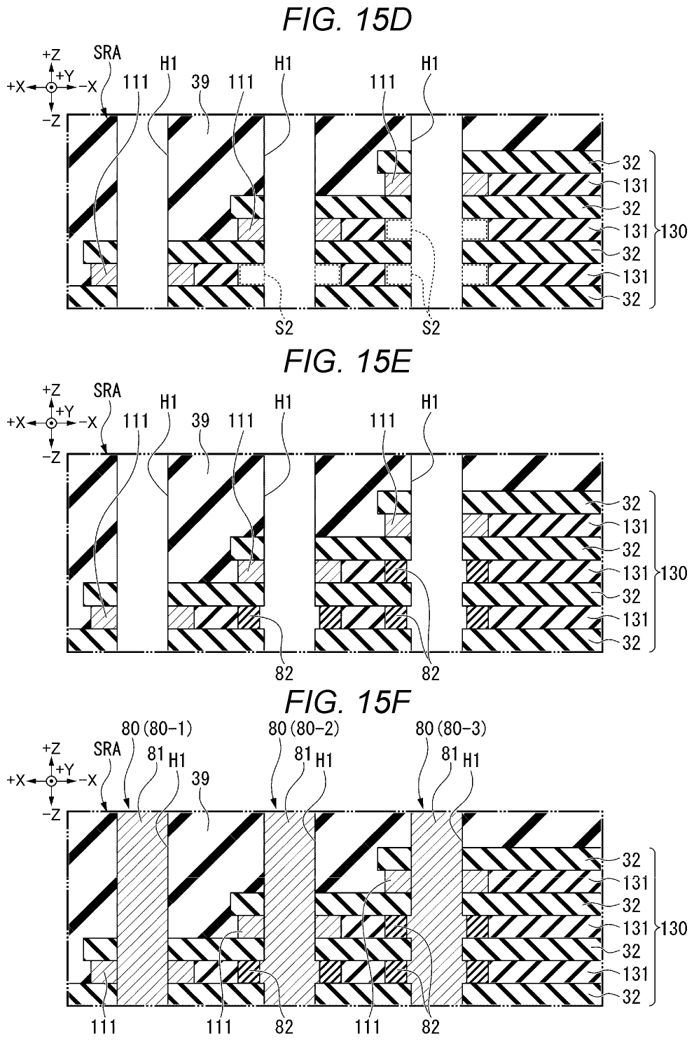

FIGS. 15A to 15F are sectional views illustrating a method of manufacturing the semiconductor storage device 1B. The present modification is such that portions differing from the manufacturing method of the first embodiment will be described.

As shown in FIG. 15A, end portions in the X direction and the Y direction of the multiple of first sacrificial layers 131 are removed by carrying out a wet etching on the stepped region SRA, in the same way as in the first embodiment. By so doing, a multiple of first space portions S1 corresponding to the removed end portions of the multiple of first sacrificial layers 131 are formed in end portions in the X direction and the Y direction of the layered body 130.

Next, as shown in FIG. 15B, a multiple of the terraced replacement formation portion 111 are formed in the multiple of first space portions S1. That is, a metal material (for example, tungsten or molybdenum) is supplied in such a way as to fill the multiple of first space portions S1, and the multiple of terraced replacement formation portions 111 are formed by an unneeded portion of the metal material being removed by etching or the like.

Next, as shown in FIG. 15C, a multiple of holes H1 are provided in the stepped region SRA in such a way as to penetrate the insulating portion 39 and the stepped region SRA in the Z direction. The multiple of holes H1 penetrate the terraced replacement formation portion 111, the multiple of first sacrificial layers 131, and the multiple of insulating layers 32 in the Z direction.

Next, as shown in FIG. 15D, etching is carried out through the multiple of holes H1 by supplying an etchant to the multiple of holes H1. By so doing, one portion of the multiple of first sacrificial layers 131 exposed in the multiple of holes H1 is removed, and a multiple of second space portions S2 corresponding to the removed one portion of the multiple of first sacrificial layers 131 are formed among the multiple of insulating layers 32.

Next, as shown in FIG. 15E, the multiple of insulating portions 82 are formed in the multiple of second space portions S2. Next, as shown in FIG. 15F, a metal material such as tungsten or molybdenum is supplied to the multiple of holes H1. By so doing, the conductive portion 81 of the multiple of contacts 80 is formed in the multiple of holes H1. Subsequently, the multiple of first sacrificial layers 131 are replaced with the multiple of conductive layers 31. By so doing, the stepped region SR is completed.

### Second Embodiment

Next, a second embodiment will be described. The second embodiment differs from the first embodiment in that one portion of the conductive portion 81 of the contact 80 protrudes to an outer side with respect to the terraced portion 101 of the conductive layer 31 that is a connection destination. Configurations other than those described hereafter are the same as in the first embodiment.

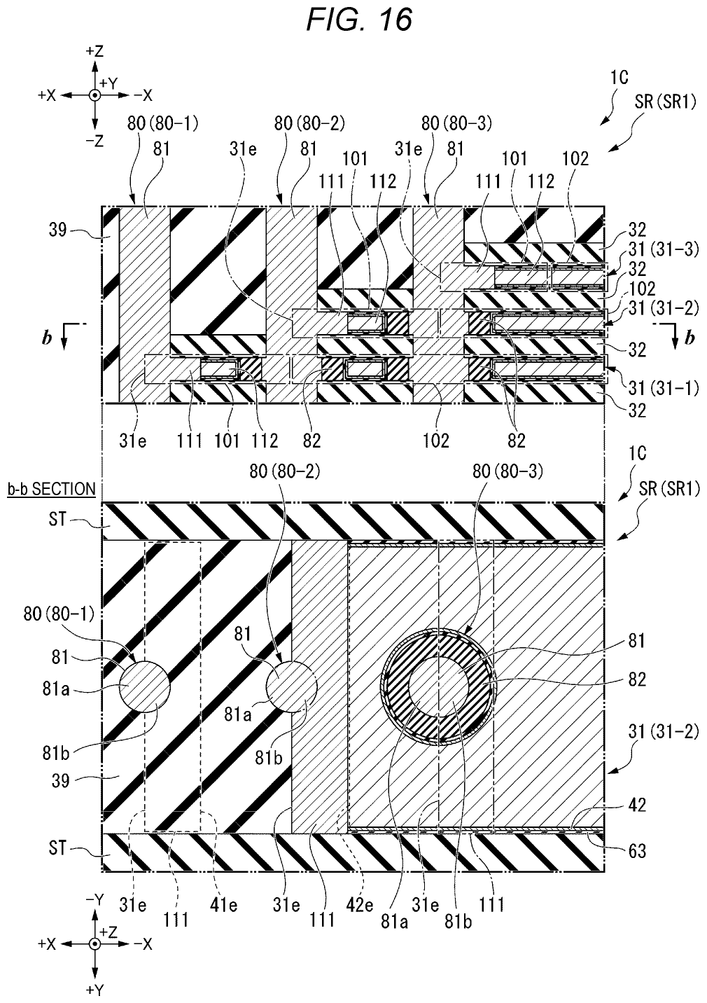

FIG. 16 is a sectional view showing one portion of a semiconductor storage device 1C of the second embodiment. In the present embodiment, one portion of the conductive portion 81 of each contact 80 is positioned farther to an outer side (that is, a side opposite to that of the non-terraced portion 102) than the end 31e in the X direction of the conductive layer 31 that is a connection destination when seen from the Z direction. The end 31e in the X direction (for example, the +X direction) of the conductive layer 31 is an end in the X direction (for example, the +X direction) of the terraced portion 101, and is an end in the X direction (for example, the +X direction) of the terraced replacement formation portion 111.

In other words, the conductive portion 81 of each contact 80 includes a first portion 81a and a second portion 81b. The first portion 81a is a portion that does not coincide with the conductive layer 31 that is a connection destination when seen from the Z direction. The second portion 81b is a portion that coincides with the conductive layer 31 that is a connection destination when seen from the Z direction.

For example, one portion of the conductive portion 81 of the second contact 80-2 is positioned farther to the +X direction side (that is, near the conductive portion 81 of the first contact 80-1) than the end 31e in the X direction of the second conductive layer 31-2 when seen from the Z direction. In the same way, one portion of the conductive portion 81 of the third contact 80-3 is positioned farther to the +X direction side (that is, near the conductive portion 81 of the second contact 80-2) than the end 31e in the X direction of the third conductive layer 31-3 when seen from the Z direction.

### Manufacturing Method

Next, a method of manufacturing the semiconductor storage device 1C will be described.

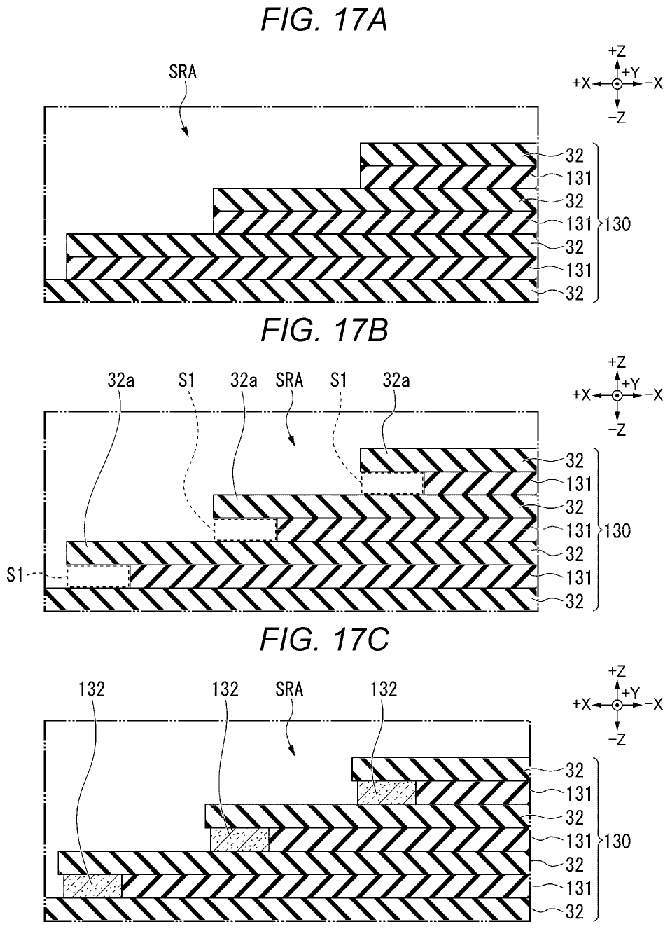

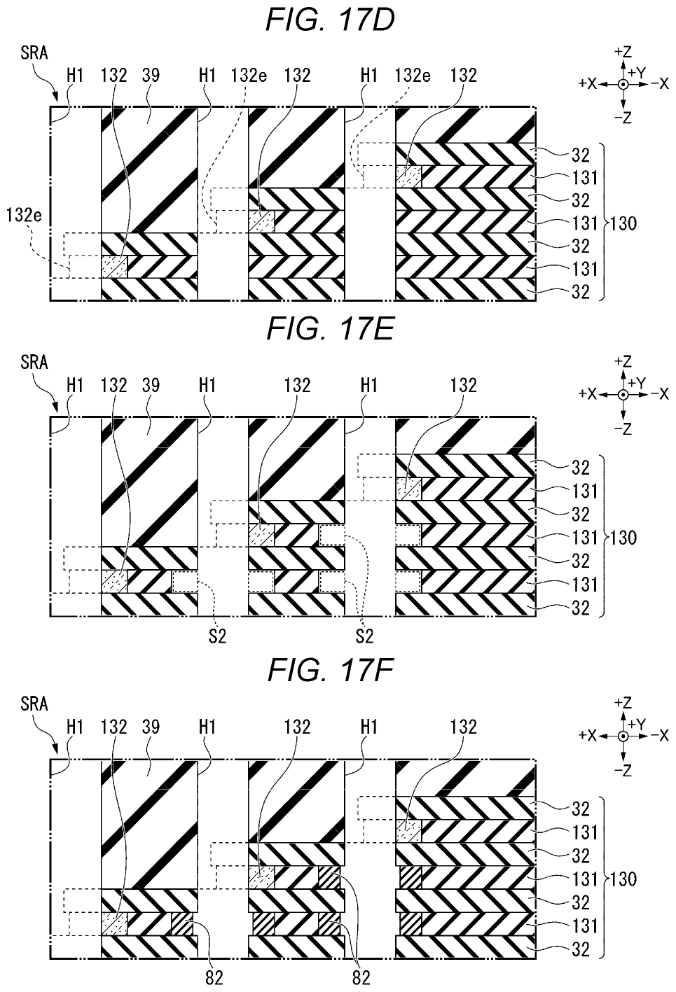

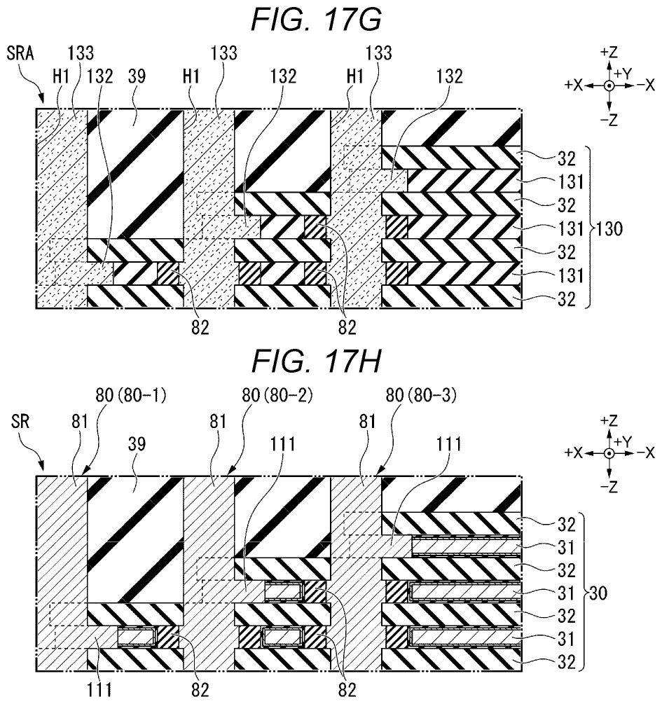

FIGS. 17A to 17H are sectional views illustrating a method of manufacturing the semiconductor storage device 1C. Hereafter, the description will be given centered on a portion relating to a formation of the stepped region SR.

Firstly, in the same way as in the case of the semiconductor storage device 1 of the first embodiment, the layered body 130 is formed by one each of the first sacrificial layer 131 and the insulating layer 32 being stacked alternately in the Z direction on a lower structure partway through manufacture.

Next, as shown in FIG. 17A, an end portion region of the layered body 130, which becomes the stepped region SR in a subsequent process, is formed in stepped form. By so doing, the stepped region SRA wherein lengths in the X direction of the multiple of first sacrificial layers 131 differ is formed.

Next, as shown in FIG. 17B, end portions in the X direction and the Y direction of the multiple of first sacrificial layers 131 are removed by carrying out a wet etching on the stepped region SRA. By so doing, a multiple of first space portions S1 corresponding to the removed end portions of the multiple of first sacrificial layers 131 are formed in end portions in the X direction and the Y direction of the layered body 130. A length in the X direction of the first space portion S1 of the present embodiment is less than a length in the X direction of the first space portion S1 of the first embodiment.

Next, as shown in FIG. 17C, a multiple of the second sacrificial layer 132 are formed in the multiple of first space portions S1. That is, sacrificial bodies are provided in such a way as to fill the multiple of first space portions S1, and the multiple of second sacrificial layers 132 are formed by an unneeded portion of the sacrificial body being removed by etching.

Next, as shown in FIG. 17D, a multiple of holes H1 are provided in the stepped region SRA in such a way as to penetrate the insulating portion 39 and the stepped region SRA in the Z direction. In the present embodiment, the hole H1 is opened in such a way that one portion of the hole H1 is positioned farther to the outer side (that is, the side opposite to that of the non-terraced portion 102) than an end 132e in the X direction of the second sacrificial layer 132.

Next, as shown in FIG. 17E, etching is carried out through the multiple of holes H1 by supplying an etchant to the multiple of holes H1. By so doing, one portion of the multiple of first sacrificial layers 131 exposed in the multiple of holes H1 is removed. Because of this, a multiple of second space portions S2 corresponding to the removed one portion of the multiple of first sacrificial layers 131 are formed among the multiple of insulating layers 32. Next, as shown in FIG. 17F, a multiple of insulating portions 82 are formed in the multiple of second space portions S2. Next, as shown in FIG. 17G, the sacrificial body 133 is formed in such a way as to fill the multiple of holes H1.

Next, as shown in FIG. 17H, the multiple of first sacrificial layers 131 are replaced with the conductive layer 31A in a state wherein a multiple of the sacrificial body 133 are provided in the multiple of holes H1. Subsequently, in the same way as in the first embodiment, the multiple of second sacrificial layers 132 are replaced with one portion (the terraced replacement formation portion 111) of the multiple of conductive layers 31, and the multiple of sacrificial bodies 133 are replaced with the multiple of conductive portions 81. Because of this, the stepped region SR is completed.

According to this kind of configuration, an increase in the reliability of the semiconductor storage device 1C can be achieved, in the same way as in the first embodiment. Also, according to the present embodiment, a width in the X direction of the terraced replacement formation portion 111 can be reduced in comparison with that in the first embodiment. Because of this, a reduction in size of the semiconductor storage device 1C can be achieved. Also, when the terraced replacement formation portion 111 is small, warping of the insulating portion 32a positioned above the first space portion S1 can be restricted even when there is no supporting body HR. Because of this, restrictions relating to a sequence of processes of forming the supporting body HR decrease in comparison with the first embodiment. This contributes to an improvement in manufacturability of the semiconductor storage device 1C.

### Third Embodiment

Next, a third embodiment will be described. The third embodiment differs from the first embodiment in that the contact 80 protrudes to an inner side with respect to the terraced replacement formation portion 111 of the conductive layer 31 that is a connection destination. Configurations other than those described hereafter are the same as in the first embodiment.

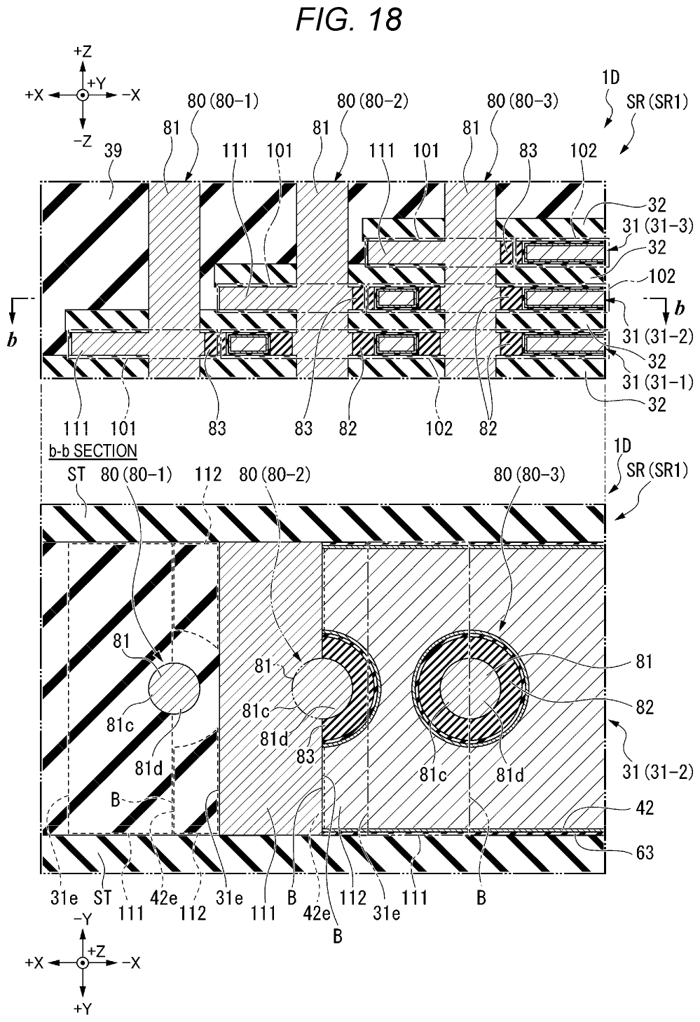

FIG. 18 is a sectional view showing one portion of a semiconductor storage device 1D of the third embodiment. In the present embodiment, one portion of the conductive portion 81 of each contact 80 is positioned farther to the inner side (that is, the non-terraced portion 102 side) than a boundary B between the terraced replacement formation portion 111 of the conductive layer 31 that is a connection destination and the normal formation portion 112 when seen from the Z direction.

In other words, the conductive portion 81 of each contact 80 includes a first portion 81c and a second portion 81d. The first portion 81c is a portion that coincides with the terraced replacement formation portion 111 of the conductive layer 31 that is a connection destination when seen from the Z direction. The second portion 81d is a portion that is positioned farther to the inner side (that is, the non-terraced portion 102 side) than the boundary B between the terraced replacement formation portion 111 of the conductive layer 31 that is a connection destination and the normal formation portion 112. In the present embodiment, an insulating portion 83 formed for manufacturing related reasons exists between the second portion 81d and the conductive layer 31.

For example, one portion of the conductive portion 81 of the first contact 80-1 is positioned farther to the −X direction side (that is, near the conductive portion 81 of the second contact 80-2) than the boundary B between the terraced replacement formation portion 111 of the first conductive layer 31-1 and the normal formation portion 112 when seen from the Z direction. One portion of the conductive portion 81 of the second contact 80-2 is positioned farther to the −X direction side (that is, near the conductive portion 81 of the third contact 80-3) than the boundary B between the terraced replacement formation portion 111 of the second conductive layer 31-2 and the normal formation portion 112 when seen from the Z direction.

This kind of configuration is also such that an increase in the reliability of the semiconductor storage device 1C can be achieved, in the same way as in the first embodiment.

### Fourth Embodiment

Next, a fourth embodiment will be described. The fourth embodiment differs from the first embodiment in that a width in the X direction of the conductive portion 81 of the contact 80 is greater than the width in the X direction of the terraced replacement formation portion 111. Configurations other than those described hereafter are the same as in the first embodiment.

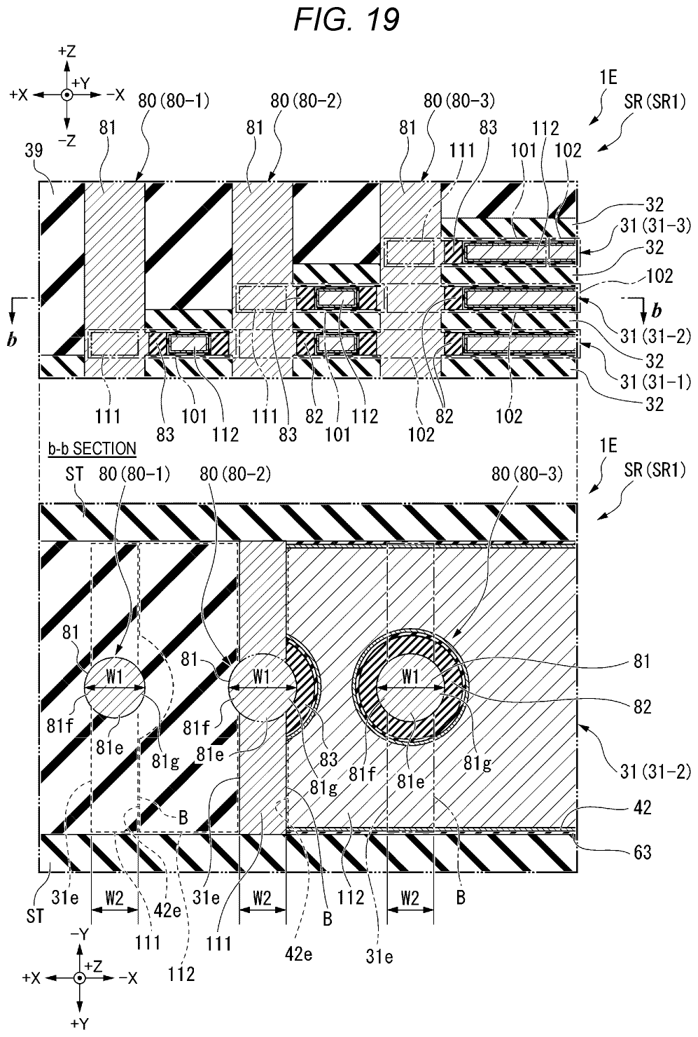

FIG. 19 is a sectional view showing one portion of a semiconductor storage device 1E of the fourth embodiment. In the present embodiment, a width W1 in the X direction of the conductive portion 81 of each contact 80 is greater than a width W2 in the X direction of the terraced replacement formation portion 111 of the conductive layer 31 that is a connection destination.

In other words, the conductive portion 81 of each contact 80 includes a first portion 81e, a second portion 81f, and a third portion 81g. The first portion 81e is a portion that coincides with the terraced replacement formation portion 111 of the conductive layer 31 that is a connection destination when seen from the Z direction. The second portion 81f is a portion that is positioned farther to the outer side (the side opposite to that of the non-terraced portion 102) than the end 31e in the X direction of the conductive layer 31 that is a connection destination. The third portion 81g is a portion that is positioned farther to the inner side (the non-terraced portion 102 side) than the boundary B between the terraced replacement formation portion 111 of the conductive layer 31 that is a connection destination and the normal formation portion 112.

For example, one portion of the conductive portion 81 of the first contact 80-1 is positioned farther to the −X direction side (that is, near the conductive portion 81 of the second contact 80-2) than the boundary B between the terraced replacement formation portion 111 of the first conductive layer 31-1 and the normal formation portion 112 when seen from the Z direction. One portion of the conductive portion 81 of the second contact 80-2 is positioned farther to the −X direction side (that is, near the conductive portion 81 of the third contact 80-3) than the boundary B between the terraced replacement formation portion 111 of the second conductive layer 31-2 and the normal formation portion 112 when seen from the Z direction.

This kind of configuration is also such that an increase in the reliability of the semiconductor storage device 1E can be achieved, in the same way as in the first embodiment.

Heretofore, some embodiments and modifications are described. Embodiments and modifications are not limited to the heretofore described examples. For example, the first modification and the second modification of the first embodiment may be realized by being combined with the embodiments from the second embodiment onward.

According to at least one of the heretofore described embodiments, a semiconductor storage device has a first columnar body and a second columnar body. The first columnar body includes a first conductive portion that penetrates a first gate electrode layer in a first direction and is electrically connected to the first gate electrode layer. The second columnar body includes a second conductive portion that penetrates a second gate electrode layer and the first gate electrode layer in the first direction, and is electrically connected to the second gate electrode layer, and an insulating portion disposed between the first gate electrode layer and the second conductive portion. According to this kind of configuration, an increase in reliability can be achieved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device, comprising:
a layered body including a plurality of gate electrode layers and a plurality of first insulating layers alternately stacked on top of one another in a first direction;
a first columnar body extending in the first direction; and
a second columnar body extending in the first direction, wherein
the gate electrode layers include a first gate electrode layer, and a second gate electrode layer that is disposed on a first side in the first direction with respect to the first gate electrode layer, and the second gate layer has a length in a second direction that intersects the first direction that is less than a length of the first gate electrode layer in the second direction,
the first columnar body includes a first conductive portion that penetrates the first gate electrode layer in the first direction and is electrically connected to the first gate electrode layer,
the second columnar body includes a second conductive portion that penetrates the second gate electrode layer and the first gate electrode layer in the first direction and is electrically connected to the second gate electrode layer, and an insulating portion disposed between the first gate electrode layer and the second conductive portion,
the first gate electrode layer includes a barrier metal film, and
at least one end portion in the second direction of the barrier metal film is positioned between at least one portion of the first conductive portion and the second conductive portion with regard to the second direction, and extends in a third direction that intersects the first direction and the second direction.

2. The semiconductor storage device according to claim 1, wherein the first gate electrode layer includes a terraced portion that does not coincide with the second gate electrode layer and a non-terraced portion that coincides with the second gate electrode layer, and
a thickness in the first direction of the terraced portion and a thickness in the first direction of the non-terraced portion are identical to each other.

3. The semiconductor storage device according to claim 1, wherein the first gate electrode layer includes a terraced portion that does not coincide with the second gate electrode layer, and
the thickness in the first direction of the terraced portion and a thickness in the first direction of the insulating portion are identical to each other.

4. The semiconductor storage device according to claim 1, wherein a thickness in the second direction of the insulating portion is equal to or greater than about 20 nm.

5. The semiconductor storage device according to claim 1, wherein at least one portion of the second conductive portion is positioned nearer than an end in the second direction of the second gate electrode layer to the first conductive portion.

6. The semiconductor storage device according to claim 1, wherein an end portion in the third direction of the layered body includes a semiconductor layer disposed between two first insulating layers included in the first insulating layers, and
the semiconductor layer includes amorphous silicon, and extends in the second direction between the two first insulating layers.

7. The semiconductor storage device according to claim 1, wherein an end portion in the third direction of the layered body includes a second insulating layer aligned with the first gate electrode layer in the third direction and a semiconductor layer disposed on a side of the second insulating layer opposite to that of the first gate electrode layer, and
the semiconductor layer extends in the second direction between two first insulating layers included in the first insulating layers.

8. The semiconductor storage device according to claim 1, wherein an end portion in the third direction of the layered body includes a second insulating layer aligned with the first gate electrode layer in the third direction and a metal layer disposed on a side of the second insulating layer opposite to that of the first gate electrode layer, and
the metal layer extends in the second direction between two first insulating layers included in the first insulating layers.

9. The semiconductor storage device according to claim 1, further comprising a supporting body that penetrates two or more gate electrode layers included in the gate electrode layers and two or more first insulating layers included in the first insulating layers in the first direction, wherein
the first gate electrode layer includes a terraced portion that does not coincide with the second gate electrode layer and a non-terraced portion that coincides with the second gate electrode layer,
the terraced portion has a first portion, which is positioned on a side of the end of the barrier metal film opposite to that of the non-terraced portion, and a second portion, which is positioned between the end of the barrier metal film and the non-terraced portion in the second direction, and
the supporting body is provided in the first portion.

10. A semiconductor storage device, comprising:
a layered body including a plurality of gate electrode layers and a plurality of first insulating layers alternately stacked in a first direction;
a first columnar body extending in the first direction; and
a second columnar body extending in the first direction, wherein
the gate electrode layers include a first gate electrode layer, and a second gate electrode layer that is disposed on a first side in the first direction with respect to the first gate electrode layer, and the second gate electrode layer has a length in a second direction that intersects the first direction less than a length of the first gate electrode layer in the second direction,
the first gate electrode layer includes a terraced portion that does not coincide with the second gate electrode layer and a non-terraced portion that coincides with the second gate electrode layer,
the first columnar body includes a first conductive portion that penetrates the terraced portion of the first gate electrode layer in the first direction and is electrically connected to the first gate electrode layer,
the second columnar body includes a second conductive portion that penetrates the second gate electrode layer and the non-terraced portion of the first gate electrode layer in the first direction and is electrically connected to the second gate electrode layer, and an insulating portion disposed between the non-terraced portion of the first gate electrode layer and the second conductive portion, and
a thickness in the first direction of the terraced portion and a thickness in the first direction of the non-terraced portion are identical to each other.

11. A semiconductor storage device manufacturing method, comprising:
forming a layered body including a plurality of first sacrificial layers and a plurality of first insulating layers alternately stacked on top of one another in a first direction;
forming a stepped region wherein respective lengths of the first sacrificial layers in a second direction that intersects the first direction differ from one another;
etching the stepped region, and removing end portions of the first sacrificial layers, thereby forming a plurality of first space portions corresponding to the removed end portions of the first sacrificial layers;
forming a plurality of holes that penetrate the first sacrificial layers in the first direction in the stepped region;
etching through the holes, and removing one portion of the first sacrificial layers exposed by the holes, thereby forming a plurality of second space portions corresponding to the removed one portion of the first sacrificial layers;
forming a plurality of insulating portions in the second space portions;
replacing the first sacrificial layers with a plurality of conductive layers; and
forming a plurality of conductive portions in the first space portions and the holes.

12. The semiconductor storage device manufacturing method according to claim 11, wherein forming the conductive portions further comprises:
forming a plurality of second sacrificial layers in the first space portions before providing the holes;
forming a plurality of sacrificial bodies in the holes after forming the insulating portions; and
replacing the second sacrificial layers and the sacrificial bodies with the conductive portions after replacing the first sacrificial layers with the conductive layers, respectively.

13. The semiconductor storage device manufacturing method according to claim 11, wherein forming the conductive portions further comprises:
forming a plurality of conductive portions in the first space portions before providing the holes; and
forming a plurality of conductive portions in the holes after forming the insulating portions.
